(19) United States
(12) Patent Application Publication
(10) Pub. No.: US 2026/0219314 A1
(43) Pub. Date: Jul. 30, 2026

(54) ALIGNMENT SYSTEM IN ELECTRONIC DEVICE TESTING

(71) Applicant: Delta Design, Inc., San Diego, CA (US)

(72) Inventor: Larry R. Stuckey, Poway, CA (US)

(21) Appl. No.: 19/461,067

(22) Filed: Jan. 27, 2026

Related U.S. Application Data
(60) Provisional application No. 63/750,177, filed on Jan. 27, 2025.

(51) Int. Cl. G01R 31/28

(52) U.S. Cl. CPC G01R 31/2887; G01R 31/2834

(57) ABSTRACT

A device testing equipment may liquify a metal in an alignment assembly, adjust an alignment between an anchoring shank and the housing of the alignment assembly such that at least one thermal head is aligned with at least one DUT for the electrical testing, and solidify the metal such that a relative position of the anchoring shank to the housing is fixed. An alignment assembly may include an anchoring shank having attached at an end thereof an anchoring member and having a vertical translational degree of freedom when the metal is molten, the anchoring member at least partly submerged in the metal, and a housing mechanically coupled to at least one thermal head to contact the at least one DUT and having defined therein a metal reservoir encapsulating the metal, the housing configured to have at least rotational degrees of freedom when the metal is molten.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims the priority benefit under 35 U.S.C. § 119(e) to U.S. Provisional Patent Application No. 63/750,177 , filed April Jan. 27, 2025, entitled “ALIGNMENT SYSTEM IN ELECTRONIC DEVICE TESTING.” The content of this application is hereby expressly incorporated by reference in its entirety.

### BACKGROUND

### Technical Field

Disclosed technology relates generally to systems and methods for testing of electronic devices, and more particularly to a system for aligning electronic devices within Automated Test Equipment (ATE).

### Description of Related Technology

Automated Test Equipment (ATE) is used in the semiconductor industry to test semiconductor devices. Generally, the automated testing equipment is configured to receive a batch or “lot” of semiconductor devices for testing. The ATE conducts testing based on predetermined settings which are dependent upon the characteristics of each device input into the ATE for testing. During actual testing, various testing systems configured to manipulate the input device's operating conditions are applied to the input device and the result is recorded.

In general, electronic devices to be tested are first placed into a tray which may be loaded into an ATE. Many types of trays are available. For example, JEDEC matrix trays may be used. These trays have standard dimensions of 12.7×5.35 inches (322.6×136 mm). Variations of these trays, such as low profile trays, with a thickness of approximately 0.25-inch (6.35 mm) can accommodate many standard electronic devices, including Ball Grid Array (BGA), Chip Scale Package (CSP), Quad Flat Package (QFP), Quad Flat No-Lead (QFN), Thin Small Outline Package (TSOP) and Small Outline Integrated Circuit (SOIC) type packaging, among many other types. High-profile JEDEC matrix trays with a height of 0.40-inches (10.16 mm) may be used to hold thicker electronic devices such as Plastic Leaded Chip Carrier (PLCC), Ceramic Quad Flat Package (CERQUAD), Pin Grid Arrays (PGA), and other modules and assemblies.

The electronic devices to be tested may be moved within the ATE by robotic equipment from the tray into various stations for running the various tests to confirm the functions of the device. During electrical testing, the electronic device is first connected to a contactor which includes a set of pins. These pins come into contact with the leads or solder balls of the device during electrical testing. Contact elements are commonly composed of a beryllium-copper base metal with gold-plating on the surface. During testing, each electronic device is inserted into the contactor for an electrical connection to the tester.

### SUMMARY

In a first aspect a method of positioning an alignment assembly of a device test equipment is described. The method can include providing the alignment assembly configured to align a device under test (DUT) for electrical testing. The alignment assembly can be mechanically coupled to a metal in a metal reservoir. The method can include adjusting the alignment assembly into a position for electrical testing of the DUT with the metal in a liquid state. The method can include solidifying the metal to lock-in the position of the alignment assembly.

In some embodiments, prior to adjusting, the metal can be in a solid state in which the alignment assembly has one or more degrees of freedom of motion restricted an the method can further include, prior to adjusting, melting the metal into the liquid state to at least partly remove the restriction to the one or more degrees of freedom of motion. In some embodiments, melting includes applying heat to the metal reservoir from outside the metal reservoir. In some embodiments, solidifying includes stopping applying heat to the metal reservoir. In some embodiments, solidifying includes actively cooling the metal reservoir. In some embodiments, solidifying includes restricting the one or more degrees of freedom of motion. In some embodiments, when the metal is liquified, the alignment assembly has one or more degrees freedom of motion selected from the group consisting of X-axis translation, Y-axis translation, Z-axis translation, rotation about X-axis, rotation about Y-axis and rotation about Z-axis. In some embodiments, when the metal is solidified, the alignment assembly is restricted with respect to one or more degrees of freedom selected from the group consisting of X-axis translation, Y-axis translation, Z-axis translation, rotation about X-axis, rotation about Y-axis and rotation about Z-axis. In some embodiments, the alignment assembly is mechanically coupled to a plunger configured to contact the DUT at a first side of the DUT. In some embodiments, the device test equipment further includes a contactor configured to contact the DUT at a second side of the DUT opposite the first side. In some embodiments, adjusting the alignment assembly into the position for electrical testing includes aligning a surface of the plunger configured to contact the DUT to be substantially parallel to a surface of the contactor configured to contact the DUT. In some embodiments, the metal has a solidus temperature above a room temperature. In some embodiments, adjusting the alignment assembly into the position for electrical testing of the DUT includes inserting an alignment DUT into the device test equipment with the metal in the liquid state. In some embodiments, the metal has a eutectic composition. In some embodiments, the eutectic composition has a eutectic melting temperature between room temperature and about 100° C. In some embodiments, the eutectic composition has a eutectic melting temperature between about 40° C. and about 80° C. In some embodiments, the eutectic composition has a eutectic melting temperature between about 55° C. and about 65° C. In some embodiments, the metal is essentially free of cadmium. In some embodiments, the metal is essentially free of lead. In some embodiments, the metal includes bismuth (Bi), lead (Pb), indium (In), tin (Sn), and cadmium (Cd). In some embodiments, the metal includes 40-50 weight % Bi, 18-28 weight % Pb, 14-24 weight % In, 3-13 weight % Sn, and 1-6 weight % Cd. In some embodiments, the metal includes 45-55 weight % Bi, 22-32 weight % Pb, 8-18 weight % Sn, and 5-15 weight % Cd. In some embodiments, the metal includes bismuth (Bi), indium (In), lead (Pb), and tin (Sn). In some embodiments, the metal includes 44-54 weight % Bi, 16-26 weight % In, 13-23 weight % Pb, and 7-17 weight % Sn. In some embodiments, the metal includes indium (In), bismuth (Bi), and tin (Sn). In some embodiments, the metal includes 46-56 weight % In, 28-38 weight % Bi, and 11-21 weight % Sn.

In a second aspect an alignment system for positioning of an alignment assembly of a device test equipment is described. The alignment system can include the alignment assembly configured to align a device under test (DUT) for electrical testing and a metal reservoir having disposed therein a metal configured to be controllably melted and solidified by the alignment system. The alignment assembly can be mechanically coupled to the metal in the metal reservoir. The alignment assembly can be configured to be adjusted into a position for electrical testing of the DUT with the metal in a liquid state. The alignment assembly can be configured to be locked-in the position with the metal in a solid state.

In some embodiments, the alignment assembly is configured to be restricted with respect to one or more degrees of freedom of motion when the metal is in the solid state. In some embodiments, the alignment assembly is further configured such that the restriction to the one or more degrees of freedom is removed when the metal is in the liquid state. In some embodiments, the alignment system can further include a heating assembly adjacent to the liquid metal reservoir for applying heat to the metal reservoir. In some embodiments, the alignment system can further include a cooling assembly adjacent to the liquid metal reservoir for actively cooling the metal reservoir. In some embodiments, when the metal is liquified, the alignment assembly has one or more degrees freedom selected from the group consisting of X-axis translation, Y-axis translation, Z-axis translation, rotation about X-axis, rotation about Y-axis and rotation about Z-axis. In some embodiments, when the metal is solidified, the alignment assembly is restricted with respect to one or more degrees of freedom selected from the group consisting of X-axis translation, Y-axis translation, Z-axis translation, rotation about X-axis, rotation about Y-axis and rotation about Z-axis. In some embodiments, the alignment assembly can be mechanically coupled to a plunger configured to contact the DUT at a first side of the DUT. In some embodiments, the device test equipment can further include a contactor configured to contact the DUT at a second side of the DUT opposite the first side. In some embodiments, device test equipment can be configured such that when the alignment assembly is in the position for electrical testing. A surface of the plunger can be configured to contact the DUT is aligned to be parallel to a surface of the contactor configured to contact the DUT. In some embodiments, the metal can have a solidus temperature above a room temperature. In some embodiments, the metal can have a eutectic composition. In some embodiments, the eutectic composition can have a eutectic melting temperature between room temperature and about 100° C. In some embodiments, the eutectic composition can have a eutectic melting temperature between about 40° C. and about 50° C. In some embodiments, the eutectic composition can have a eutectic melting temperature between about 55° C. and about 65° C. In some embodiments, the metal can be essentially free of cadmium. In some embodiments, the metal can be essentially free of lead. In some embodiments, the metal can include bismuth (Bi), lead (Pb), indium (In), tin (Sn), and cadmium (Cd). In some embodiments, the metal can include 40-50 weight % Bi, 18-28 weight % Pb, 14-24 weight % In, 3-13 weight % Sn, and 1-6% Cd. In some embodiments, the metal can include 45-55 weight % Bi, 22-32 weight % Pb, 8-18 weight % Sn, and 5-15 weight % Cd. In some embodiments, the metal can include bismuth (Bi), indium (In), lead (Pb), and tin (Sn). In some embodiments, the metal can include 44-54 weight % Bi, 16-26 weight % In, 13-23 weight % Pb, and 7-17 weight % Sn. In some embodiments, the metal can include indium (In), bismuth (Bi), and tin (Sn). In some embodiments, the metal can include 46-56 weight % In, 28-38 weight % Bi, and 11-21 weight % Sn.

In a third aspect, a device test equipment is described. The device test equipment can include an alignment system according to the second aspect.

In a fourth aspect, a method of aligning device test equipment for electrical testing of at least one device under test (DUT) is described, the method including: liquifying a metal in an alignment assembly, wherein the alignment assembly includes: an anchoring shank having attached at an end thereof an anchoring member and having a vertical translational degree of freedom when the metal is molten, the anchoring member at least partly submerged in the metal, and a housing mechanically coupled to at least one thermal head to contact the at least one DUT and having defined therein a metal reservoir encapsulating the metal, the housing configured to have at least rotational degrees of freedom when the metal is molten; adjusting an alignment between the anchoring shank and the housing such that the at least one thermal head is aligned with the at least one DUT for the electrical testing; and solidifying the metal such that a relative position of the anchoring shank to the housing is fixed.

In some embodiments, the at least one DUT is housed in a coupon, the at least one DUT having one or more degrees of freedom within the coupon. In some embodiments, adjusting the alignment between the anchoring shank and the housing includes moving the anchoring shank along the vertical translational degree of freedom. In some embodiments, adjusting the alignment between the anchoring shank and the housing includes rotating the housing about at least one rotational degree of freedom. In some embodiments, prior to liquifying the metal, the alignment between the anchoring shank and the housing is restricted such that one or more degrees of freedom of motion is fixed. In some embodiments, liquifying the metal includes applying heat to the metal reservoir from outside the metal reservoir. In some embodiments, solidifying includes stopping applying heat to the metal reservoir. In some embodiments, solidifying includes applying active cooling to the metal reservoir. In some embodiments, solidifying includes restricting the one or more degrees of freedom of motion. In some embodiments, the alignment assembly further includes a fluidic channel disposed in the housing and configured to circulate a fluid. In some embodiments, liquifying the metal includes circulating a heating fluid through the fluidic channel. In some embodiments, solidifying the metal includes circulating a cooling fluid through the fluidic channel. In some embodiments, when the metal is liquified, the alignment assembly has one or more degrees freedom of motion selected from the group consisting of X-axis translation, Y-axis translation, Z-axis translation, rotation about X-axis, rotation about Y-axis and rotation about Z-axis. In some embodiments, when the metal is solidified, the alignment assembly is restricted with respect to one or more degrees of freedom selected from the group consisting of X-axis translation, Y-axis translation, Z-axis translation, rotation about X-axis, rotation about Y-axis and rotation about Z-axis. In some embodiments, adjusting the alignment between the anchoring shank and the housing includes contacting the at least one thermal head with the DUT on a first side of the DUT. In some embodiments, adjusting the alignment between the anchoring shank and the housing further includes contacting a contactor of the device test equipment with the DUT at a second side of the DUT opposite the first side. In some embodiments, adjusting the alignment between the anchoring shank and the housing includes aligning a surface of the at least one thermal head with the DUT to be substantially parallel to a surface of the DUT.

In a fifth aspect, an alignment system for positioning of an alignment assembly of a device test equipment is described, the alignment system including: an alignment assembly including: an anchoring shank having attached at an end thereof an anchoring member and having a vertical translational degree of freedom when a metal is molten, the anchoring member at least partly submerged in the metal, and a housing mechanically coupled to at least one thermal head to contact the a device under test (DUT) and having defined therein a metal reservoir encapsulating the metal, the housing configured to have at least rotational degrees of freedom when the metal is molten; wherein when the metal is in a liquid state the in the alignment assembly, an alignment between the anchoring shank and the housing is free to be adjusted for aligning the at least one thermal head with the DUT for electrical testing; and wherein when the metal is in a solid state a relative position of the anchoring shank to the housing is fixed.

In some embodiments, the DUT is housed in a coupon, the DUT having one or more degrees of freedom within the coupon. In some embodiments, adjusting the alignment between the anchoring shank and the housing includes moving the anchoring shank along the vertical translational degree of freedom. In some embodiments, adjusting the alignment between the anchoring shank and the housing includes rotating the housing about at least one rotational degree of freedom. In some embodiments, the alignment assembly further includes a fluidic channel disposed in the housing and configured to circulate a fluid. In some embodiments, the fluidic channel is configured to circulate a heating fluid such that the metal is liquified from the solid state. In some embodiments, the fluidic channel is configured to stop circulating the heating fluid such that the liquified metal is solidified. In some embodiments, the fluidic channel is configured to circulate a cooling fluid such that the metal is solidified from the liquid state. In some embodiments, when the metal is in the liquid state, the alignment assembly has one or more degrees freedom of motion selected from the group consisting of X-axis translation, Y-axis translation, Z-axis translation, rotation about X-axis, rotation about Y-axis and rotation about Z-axis. In some embodiments, when the metal is in the solid state, the alignment assembly is restricted with respect to one or more degrees of freedom selected from the group consisting of X-axis translation, Y-axis translation, Z-axis translation, rotation about X-axis, rotation about Y-axis and rotation about Z-axis. In some embodiments, adjusting the alignment between the anchoring shank and the housing includes contacting the at least one thermal head with the DUT on a first side of the DUT. In some embodiments, adjusting the alignment between the anchoring shank and the housing further includes contacting a contactor of the device test equipment with the DUT at a second side of the DUT opposite the first side. In some embodiments, adjusting the alignment between the anchoring shank and the housing includes aligning a surface of the at least one thermal head with the DUT to be substantially parallel to a surface of the DUT.

In a sixth aspect, a device test equipment for electrical testing of a device under test (DUT) is described, the device test equipment including: a contactor configured to make electrical connection with the DUT; and an alignment assembly including: an anchoring shank having attached at an end thereof an anchoring member and having a vertical translational degree of freedom when a metal is molten, the anchoring member at least partly submerged in the metal, and a housing mechanically coupled to a thermal head to contact the DUT and having defined therein a metal reservoir encapsulating the metal, the housing configured to have at least rotational degrees of freedom when the metal is molten; wherein the device test equipment is configured to: liquify the metal in the alignment assembly, adjust an alignment between the anchoring shank and the housing such that the thermal head, the DUT, and the contactor are aligned for electrical testing, and solidify the metal such that a relative position of the anchoring shank to the housing is fixed.

In some embodiments, the DUT is housed in a coupon, the DUT having one or more degrees of freedom within the coupon. In some embodiments, to adjust the alignment between the anchoring shank and the housing the device test equipment is configured to move the anchoring shank along the vertical translational degree of freedom. In some embodiments, to adjust the alignment between the anchoring shank and the housing the device test equipment is configured to rotate the housing about at least one rotational degree of freedom. In some embodiments, when the metal is in a liquid state, the alignment between the anchoring shank and the housing is restricted such that one or more degrees of freedom of motion is fixed. In some embodiments, to liquify the metal the device test equipment is configured to apply heat to the metal reservoir from outside the metal reservoir. In some embodiments, to solidify the device test equipment is configured to stop applying heat to the metal reservoir. In some embodiments, to solidify the device test equipment is configured to apply active cooling to the metal reservoir. In some embodiments, solidifying includes restricting the one or more degrees of freedom of motion. In some embodiments, the alignment assembly further includes a fluidic channel disposed in the housing and configured to circulate a fluid. In some embodiments, to liquify the metal the device test equipment is configured to circulate a heating fluid through the fluidic channel. In some embodiments, to solidify the metal the device test equipment is configured to circulate a cooling fluid through the fluidic channel. In some embodiments, when the metal is liquified, the alignment assembly has one or more degrees freedom of motion selected from the group consisting of X-axis translation, Y-axis translation, Z-axis translation, rotation about X-axis, rotation about Y-axis and rotation about Z-axis. In some embodiments, when the metal is solidified, the alignment assembly is restricted with respect to one or more degrees of freedom selected from the group consisting of X-axis translation, Y-axis translation, Z-axis translation, rotation about X-axis, rotation about Y-axis and rotation about Z-axis. In some embodiments, to adjust the alignment between the anchoring shank and the housing the device test equipment is configured to contact thermal head with the DUT on a first side of the DUT. In some embodiments, to adjust the alignment between the anchoring shank and the housing the device test equipment is further configured to contact the contactor to the DUT at a second side of the DUT opposite the first side. In some embodiments, adjusting the alignment between the anchoring shank and the housing includes aligning a surface of the thermal head with the DUT to be substantially parallel to a surface of the DUT.

### BRIEF DESCRIPTION OF THE DRAWINGS

Embodiments of this disclosure will be described, by way of non-limiting example, with reference to the accompanying drawings.

FIGS. 1A and 1B illustrate perspective front and side views of an electronic device testing system according to various embodiments.

FIG. 1C illustrates a top-down view of the electronic device testing system illustrated in FIGS. 1A and 1B according to various embodiments.

FIG. 1D illustrates a platter assembly for rotating carrier retainer disks around stations of the electronic testing system according to embodiments.

FIG. 2 is an example process of testing devices under test using an electronic device testing system according to various embodiments.

FIG. 3 illustrates a block diagram of a testing station according to various embodiments.

FIGS. 4A-4E illustrate an alignment system used in a testing system according to various embodiments.

FIG. 5 illustrates an alignment assembly and guide shaft according to an embodiment.

FIGS. 6A-6C illustrate an alignment assembly according to various embodiments.

FIGS. 7A and 7B illustrate aspects of heating a cooling metal in an alignment assembly according to various embodiments.

FIGS. 8A-8C illustrate an example process of aligning a socket layout kit device under test, and loadboard according to various embodiments.

FIG. 9 illustrates a carrier assembly according to various embodiments.

FIG. 10 illustrates a plunger assembly according to various embodiments.

FIG. 11 illustrates an example socket layout kit according to various embodiments.

FIG. 12 illustrates a loadboard according to various embodiments.

FIG. 13 illustrates a socket according to various embodiments.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the embodiments. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the illustrated elements. Further, some embodiments can incorporate any suitable combination of features from two or more drawings.

### Testing System Overview

Aspects of this disclosure relate to Automated Testing Equipment, also called an “electronic device testing system”, with improved reliability, efficiency and/or cost associated with testing electronic components. The electronic device testing system may provide automation for testing electronic devices or components. The electronic devices can include, but are not limited to, semiconductor device components, including packaged and unpackaged integrated circuit (IC) dies including monolithically integrated IC dies as well as bonded or stacked IC dies that include passive and/or active circuitry. Such dies can include integrated circuits, such as logic circuitry, volatile and nonvolatile memory circuitry, power delivery circuitry, photonic integrated circuitry, to name a few. The electronic devices that are being tested in the electronic testing system may be referred to as devices under test (“DUTs”).

Types of electronic device packages which may be tested within the electronic device testing systems described herein include Ball Grid Arrays (BGA), Chip Scale Packages (CSP), Quad Flat Packages (QFP), Quad Flat No-Leads (QFN), Thin Small Outline Packages (TSOP), Small Outline Integrated Circuit (SOIC), Plastic Leaded Chip Carrier (PLCC), Ceramic Quad Flat Package (CERQUAD), and Pin Grid Arrays (PGA). Other types of packages are also contemplated within embodiments of the invention.

Many challenges of designing electronic device testing systems arise from handling the IC packages, e.g., using vacuum handlers, as they are transferred and probed. One of the challenges is reducing the displacement of a DUT during operation of the testing equipment (sometimes referred to as “device out of pocket”), which is often caused in part due to handling of the DUTs. Another challenge is reducing DUTs being stuck within components of the testing equipment, such as handlers or contactors. Another challenge is keeping the DUTs at a temperature closer to the test temperature prior to testing the individual DUTs to improve throughput. Another challenge is keeping the testing environment substantially dry to reduce condensation on the DUTs that might occur when transported into the testing system from ambient temperature.

To address these and other needs, the disclosed electronic device testing systems are configured to transfer DUTs from a tray into a carrier assembly. The carrier assembly moves through a plurality of stations and through completion of the testing of the DUTs, without transferring the DUTs out of the carrier assembly. The DUTs are carried in the carrier assembly as the carrier assembly is moved from one station to another within the system. The DUTs are retained in the carrier assembly using a plurality of “coupons” that are attached to the carrier assembly, but the coupons are allowed limited lateral and vertical movements and degrees of freedom while being carried in the carrier and placed in the testing station, until the DUTs are tested. Prior to testing in a testing station and/or during pretesting procedures, the coupons may be allowed limited lateral and vertical movements and degrees of freedom. For example, the coupons may at times have up to six degrees of freedom, including three independent linear degrees of freedom and three independent angular degrees of freedom, until the coupons are secured during testing. The six degrees of freedom can help the DUTs within the coupons to properly align with components of the system, such as a contactor. The stations include an electronic testing station where the DUTs are tested in the carrier assembly without being removed from the carrier assembly or the coupons. In the electronic testing station, a contactor electrically contacts the DUTs retained in the carrier assembly to send and receive electrical signals. The signals can include, e.g., testing signals as well as power signals to power the DUTs. The temperature of the DUTs may also be controlled, e.g., actively controlled, during testing using plunger assemblies contacting the DUTs on the opposite side of the contactor. The plunger assemblies may be equipped with an automatic temperature control (ATC) system including a heater and cooler for maintaining a substantially constant temperature DUT temperature during testing. In addition, the contactor may be connected to a cooling system and incorporate a heater to help maintain the DUT at a predetermined temperature during testing.

The system may also include other stations through which the DUTs are transported in carrier assemblies including, for example, a thermal staging area (which can include one or more soak stations) preceding the testing station. To improve throughput, the DUTs may be brought and kept at a temperature closer to the testing temperature prior to testing. To reduce the lag time associated with bringing the DUTs closer to the testing temperature, the one or more soak stations in the thermal staging area and the testing station are enclosed in a thermal chamber under a common temperature-controlled atmosphere.

In some embodiments, the carrier assemblies remain on carrier retainer disks throughout the thermal chamber or the thermal chamber and the dry chamber without being stacked. However, embodiments are not so limited and in some other embodiments, the carrier assemblies may be stacked into a stack and singulated from the stack in the thermal staging area prior to being tested. For example, a carrier assembly may be loaded to a first soak station having a stack of carrier assemblies, raised to the top of the stack as other carrier assemblies are loaded, moved laterally into a second soak station, where it is lowered into position before continuing to the testing station.

In some embodiments, the thermal staging area includes more than one soak station for carrier assemblies. This can create a lag time allowing the carrier assemblies and DUTs to reach their target temperature before moving into the testing station. In some instances, the lag time may be approximately defined by the time used for testing and the number of positions for the carrier assemblies in the thermal staging area.

The thermal chamber keeps the DUTs closer to the testing temperature by circulating temperature-controlled gas such as clean dry air. The thermal chamber may also be held under a positive pressure of clean dry air to minimize any condensation that may occur on the DUTs. In addition, an input station at which the untested DUTs are introduced into carrier assemblies, an output station from which the tested DUTs are unloaded, and a tray precising station (TPS), from which DUTs on a tray in a tray frame are pick-and-placed in the carrier assembly in the input or output station, may also be kept at a positive pressure of clean dry air, which may be at room temperature, in a separate dry chamber to reduce any moisture that may enter into the thermal chamber.

In addition, the disclosed electronic testing systems are configured to transfer the carrier assemblies carrying the DUTs from one station to the next by rotating carrier retainer disks retaining the carriers in a circular pattern using a platter assembly. The carrier assemblies rotate about a vertical axis of the device testing system, without using robotic arms or handlers to move the carrier assemblies. Each carrier retainer disk may also rotate about its own central axis to compensate for the rotation about the vertical axis, such that the carrier assemblies remain substantially aligned in the same direction through completion of the testing. This process maintains each DUT within a carrier in the same position while in the test system and helps reduce jostling and damage that may come from moving the DUTs within the test system during the transfer from station to station. This may also significantly reduce jams caused by displacements of the DUTs or DUTs being stuck on or within testing components or stations.

In addition, the disclosed electronic testing systems include a DUT tray input/output system for transferring untested DUTs onto the carrier assemblies in the thermal chamber and transferring tested DUTs out of the carrier assemblies and out of the thermal chamber back to a tray, using a pick-and-place handler. In one embodiment, the system may use tray frames configured to mate with the trays to pick up and move the trays into and out of the system. The DUT tray input/output system may include as few as three motor drives configured to transfer the trays, held by the tray frames, into and out of the thermal chamber. The DUTs within the trays may be monitored and identified using a vision monitoring system prior to being placed in the carrier assemblies for tracking. The tray frames may be made of an inflexible material, such as metal, so that when they mate with a tray, they can reduce any tray warpage and straighten and align the trays for pick and place precision movement. This may also help to further reduce displacement of DUTs from the trays due to tray warpage.

In some aspects, the electronic device testing system disclosed herein may intake DUTs that are to be tested, index the DUTs, test the DUTs, record the results of testing, and output the indexed and tested DUTs while reducing instances of DUT displacements. The disclosed electronic device testing system may increase DUT throughput, reduce testing stoppage, reduce repairs or other maintenance, and/or provide other benefits.

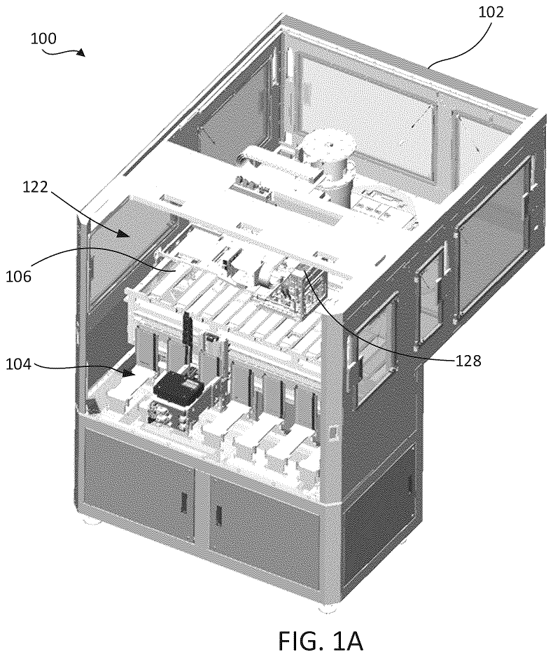

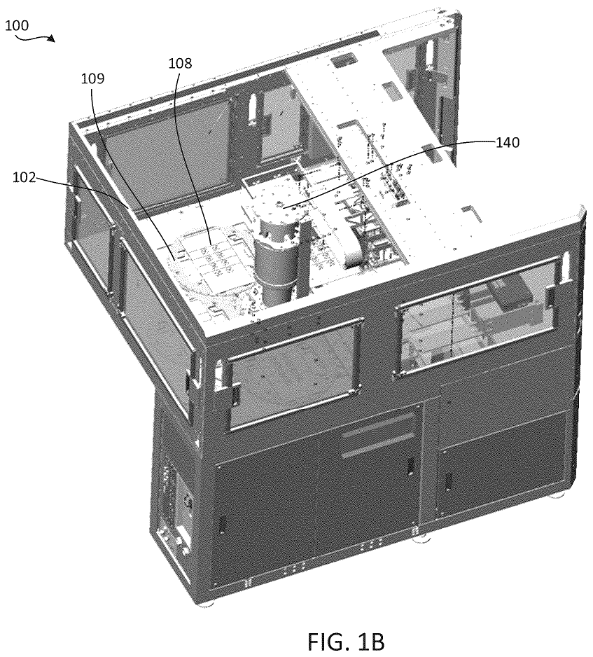

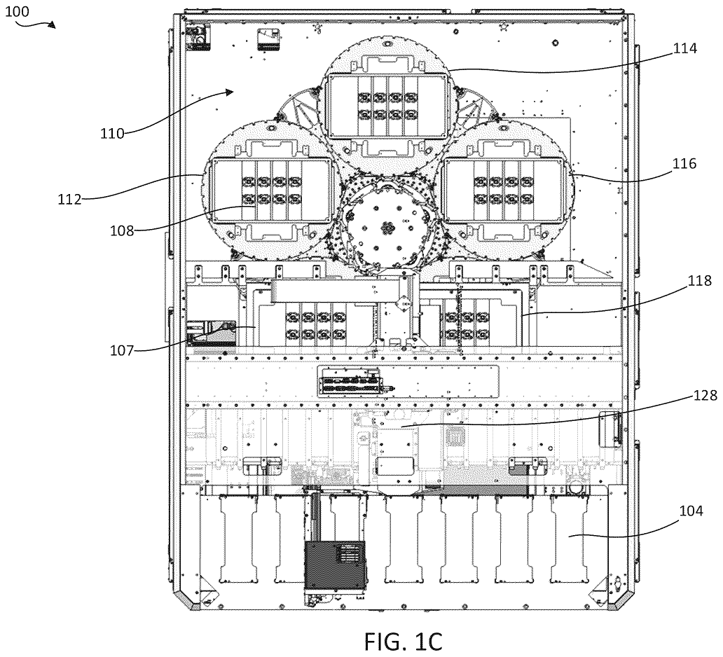

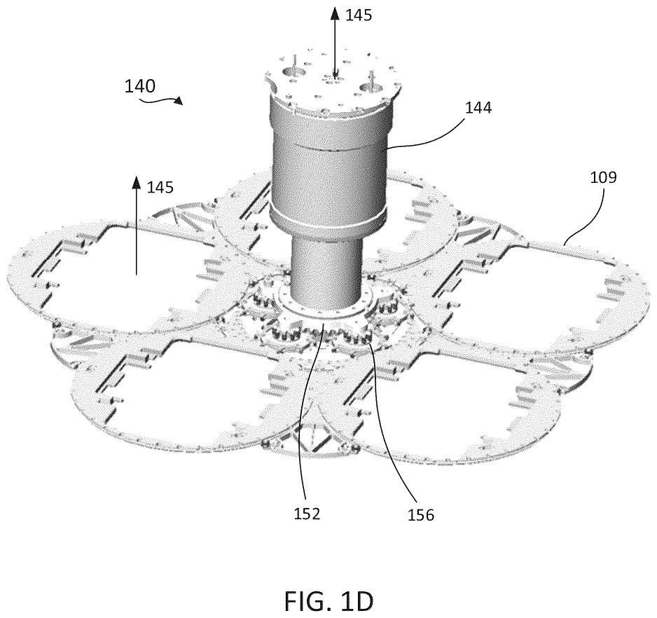

FIGS. 1A-1C illustrate an electronic device testing system 100, according to various embodiments. FIGS. 1A and 1B are perspective front and side views and FIG. 1C is a top-down view of the device testing system 100. In the illustrated embodiment, the electronic device testing system 100 includes tray stacks 104 (FIG. 1A; actual stacks not shown) an input station 107, carriers 108 (FIGS. 1A-1C), carrier retainer disks 109 (FIG. 1B), a thermal staging area 110 (FIG. 1C), which can include one or more soak stations 112, 114 (FIG. 1C), a testing station 116 (FIG. 1C), and an output or sort station 118 (FIG. 1C). In the illustrated embodiment, the electronic device testing system 100 additionally includes a tray precising station (TPS) 106 (FIGS. 1A, 1C) from which DUTs in a tray are transferred into the input station 107 and out of the output station 118 using a pick-and-place (PnP) head 128 (FIGS. 1A, 1C). In the electronic testing system 100, as described above, the one or more soak stations 112, 114 of the thermal staging area 110 and the testing station 116 may be in a thermal chamber 102 (FIG. 1A. 1B) under temperature-controlled atmosphere under positive pressure to bring DUTs close to testing temperature. The temperature inside the thermal chamber 102 is controlled in part by introducing temperature-controlled gas, e.g., temperature controlled clean dry air. The atmosphere in the thermal chamber 102 may further be controlled, e.g., to reduce the moisture content and condensation on the DUTs. Further, the input station 107, the output station 118 and the TPS 106 may be in a dry chamber 122 (FIG. 1A) under positive pressure to reduce condensation on the DUTs upon introduction into the thermal chamber 102.

In some embodiments, the electronic device testing system 100 may be connected to one or more heat exchangers through inlet and outlet pipes. The heat exchanger may comprise one or more condensers for circulating temperature-controlled gas, e.g., chilled clean dry air, or other gas such as argon, helium, etc. in the thermal chamber 102 and/or the thermal staging area 110 to maintain the temperature-controlled atmosphere therein. In some embodiments, the temperature-controlled gas may be introduced into the thermal chamber 102 and/or the thermal staging area 110 through a temperature-controlled gas conduit disposed close to the thermal staging area 110. Additional heat exchangers may be employed to provide a cold source for one or both of a contactor and a plunger, which may be configured, in conjunction with a heater, to provide automatic temperature control of the DUT during testing. The temperature of the DUT may be maintained, e.g. at a temperature between about −50° C. and 200° C.

Among other technical features described throughout the application, in various embodiments, in operation of the system 100 according to embodiments, the DUTs are transferred within the system 100 through usage of the carriers 108, without handling DUTs out of the carriers 108 as the DUTs are transferred though different stations. Unlike existing systems, once the DUTs are transferred onto the carriers 108, the station-to-station transfers and testing of the DUTs are performed without removing them from the carriers 108, which greatly reduces device displacement events, as there may not be a need for handling the DUTs using, e.g., vacuum handlers. until after the testing is completed. The reduced handling of the DUTs greatly reduces the probability of displacing the DUTs, which has traditionally been one of the biggest throughput limiters of IC testing.

The tray stacks 104 can include trays of DUTs that are to be tested or have completed testing. Each tray in the tray stack 104 can include one or more DUTs. For example, each tray in the tray stack 104 can include one, two, four, eight, twenty, fifty, or other number of DUTs. In the illustrated implementation, the tray stacks 104 are positioned outside of the thermal chamber 102.

In some implementations, in addition to the control of the ambient temperature in the thermal chamber 102, there can also be a pressure difference between the thermal chamber 102 and the area in which the tray stacks 104 are positioned. For example, the thermal chamber 102 may have, e.g., a positive pressure of temperature-controlled dry gas such as air, nitrogen or other inert gas (e.g., He or Ar). The positive pressure may be maintained by a continuous purge of the thermal chamber 102 with the temperature-controlled dry gas. Similarly, the dry chamber 122 may also have a positive pressure, e.g., a positive pressure of temperature-controlled dry gas. The positive pressure configurations can keep moisture from condensing on the DUTs or other parts of the system, which can interfere with the testing. For example, without such purge, DUTs that are cooled may collect excessive moisture condensation.

The TPS 106 can carry, or otherwise transfer, trays from the tray stacks 104 into the thermal chamber 102. In some embodiments, the TPS 106 includes tray frames that temporarily physically couple to a tray of the tray stack 104 and carry the tray into the thermal chamber 102. The TPS 106 can carry, or otherwise transfer trays, such as trays of DUTs having completed testing, from the dry chamber 122 to the tray stacks 104. The TPS 106 can include, or be connected to, the input station 107 and the output station 118.

The PnP head 128 can transfer DUTs from a tray inputted into the dry chamber 122 from the TPS 106 and place them onto carriers 108 on the input station 107. The PnP head 128 can also carry DUTs from a carrier 108 on the output station 118 and place them onto trays in the TPS 106 to be carried out of the dry chamber 122. In various implementations, the input station 107 and the output station 118 can be configured to pick up DUTs one at a time, or in sets. For example, the PnP head 128 can include one or more vacuum contact points to temporarily couple the DUTs to transfer them to the carrier 108 on the input station 107 or from the carrier 108 on the output station 118.

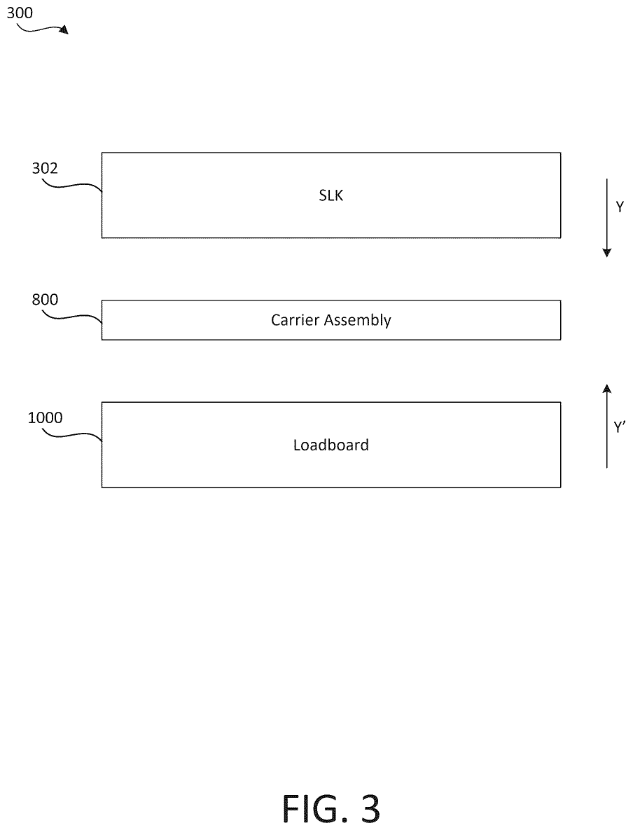

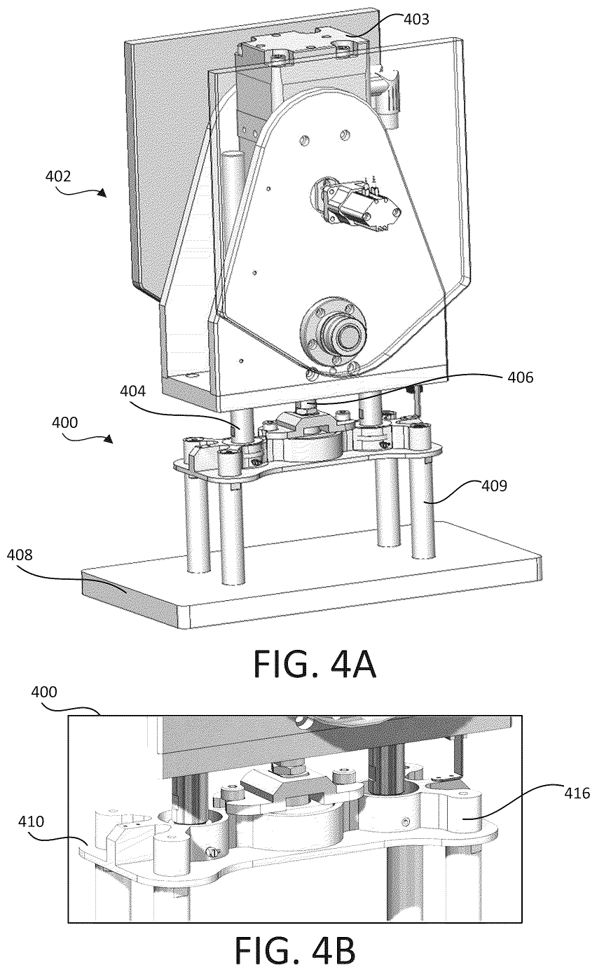

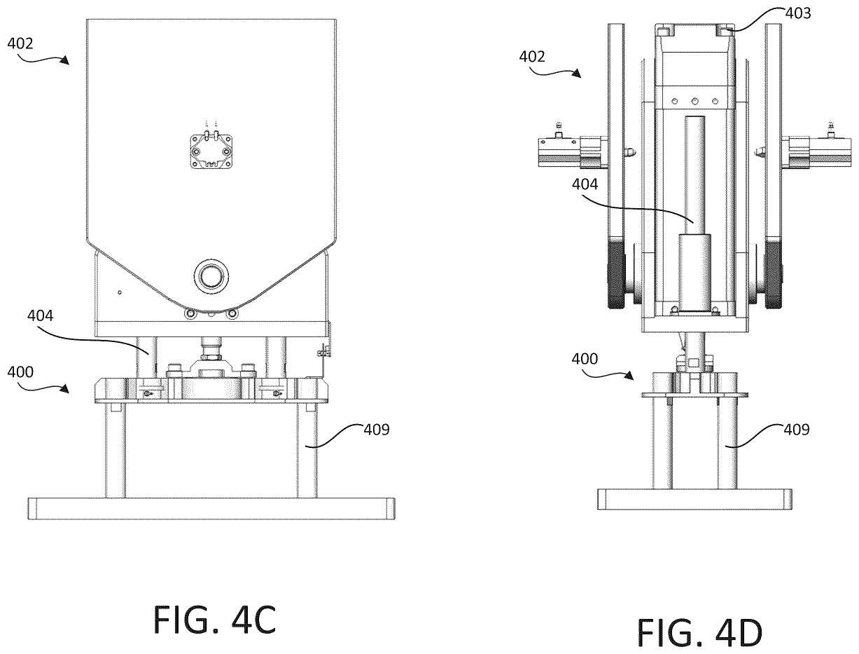

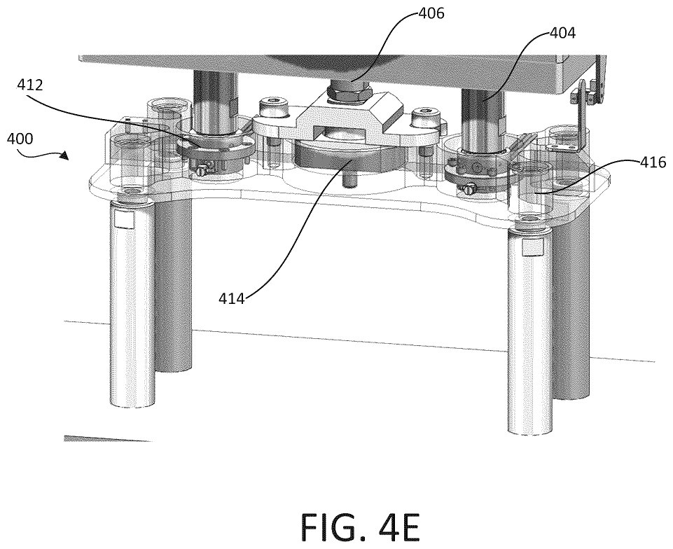

The carriers can include one or more coupons. Each coupon may be configured to carry one or more DUTs. While placed in a carrier, a coupon may have up to six degrees of freedom of movement, including three linear degrees of freedom along lateral, e.g., x and y directions, and the vertical direction, e.g., z direction, and three rotational degrees of freedom about the x, y and z axes (also referred to as pitch, roll and yaw). The degrees of freedom may be provided by, e.g., springs holding the coupons within the carrier. The degrees of freedom may allow the coupons to move within the carrier without damaging the coupons and/or dislodging the coupons. The DUT may be secured using one or more securing mechanisms (e.g., the holder 404 and the holder 405, described herein with respect to FIG. 3D and FIGS. 4D and 4E). The coupon may allow a testing orientation to remain. For example, the pin orientation of the DUT may be maintained within the coupon as the carriers are transported to the different stations.

The carriers 108 may be transported between different stations by the carrier retainer disks 109. The carrier retainer disks 109 are configured to hold and transfer the carriers 108 from one station to the next. While being transferred, the carriers 108 are coupled or temporarily coupled to the carrier retainer disks 109. In some implementations, the carriers 108 are placed on the carrier retainer disks 109. In the illustrated implementation, the carrier retainer disks 109 rotate the carriers 108 sequentially from the input station 107 to the thermal staging area 110 (which is illustrated as having two soak stations 112, 114), followed by the testing station 116, and followed by the output station 118.

In some embodiments, the carrier retainer disks 109 are configured such that, as they are rotating, the orientations of the carriers 108 are kept substantially constant. For clarity, FIG. 1D shows an example platter assembly 140 configured for such operations. The platter assembly 140 includes a torque motor 144 configured to rotate a platter having a plurality of arms, each having disposed thereon a carrier retainer disk 109 configured to carry a carrier 108. The platter assembly 140 additionally includes a sun gear 152 and a plurality of planet gears 156 each corresponding to a carrier retainer disk 109. The torque motor 144 causes the sun gear 152 to rotate, which in turn causes the planet gears 152 to rotate. The planet gears 152 and the carrier retainer disks 109 are toothed to mesh with each other such that the carrier retainer disks 109 rotate in the opposite sense as the sun gear 152. For example, as the carrier retainer disks 109 are rotating from one station to the next in a clockwise direction about a central axis 125 of the system, they are rotated in a counterclockwise direction to offset for the rotations of the carrier retainer disks 109 about their own local central axes 145.

The thermal staging area 110 can heat the DUTs and/or cool the DUTs to set temperatures, such as a testing temperature (also referred to as “soaking” the DUTs). A testing temperature can refer to a temperature the DUTs are to be at when testing begins. The thermal staging area 110 can include a first soak station 112 and a second soak station 114. In some instances, the time required for a DUT to reach a testing temperature in the thermal staging area 110 may be different (e.g., shorter or longer) than the time required for testing in the testing station 116. The thermal staging area 110 can include multiple soak stations for the carriers 108. The carriers 108 can be brought into a first soak station 112 in the thermal staging area 110 where the carriers 108 are soaked for an amount of time (e.g., approximately the time it takes to complete a test of DUTs in the testing station). Then the carriers 108 can be brought into a second soak station 114 of the thermal staging area 110 where the carriers are further soaked for an amount of time (which can be approximately equal to the amount of time in the first station of the thermal staging area 110).

In embodiments where soak stations are configured to stack and unstack multiple carrier, the carriers 108 can be brought into the first soak station 112 (which may also be referred to as a soak up station) and/or the second soak station 114 (which may also be referred to as a soak down station) by the carrier retainer disks 109 where each new carrier 108 is added to a stack. A carrier 108 can be removed from a stack in the soak up station 112 and/or the soak down station 114 and placed back onto the carrier retainer disks 109. A carrier 108 can remain in a stack in the soak up station 112 and/or soak down station 114. In some implementations, carriers 108 can be rotated by the carrier retainer disks 109 into the soak up station 112 where they can be stacked. Each carrier 108 arriving at the soak up station is inserted into a slot created at the bottom of the stack of carriers 108 such that vertical handling of the carriers is reduced. The DUTs in their respective carriers 108 soak to a temperature setpoint as the carriers 108 are stacked up. The stack of carriers 108 can be rotated by a carrier retainer disk 109 from the soak up station 112 into the soak down station 114, from which the carriers 108 are singulated and moved to the testing station 116.

While FIGS. 1A-1C illustrate the thermal staging area 110 as having two separate soak stations, in various implementations, the thermal staging area 110 may have a single station or more than two stations. In some implementations, the thermal staging area 110 may be omitted altogether and the carriers transferred directly from the input station 107 to the testing station 116. In yet other implementations, the testing station may be between two soak stations. 109.

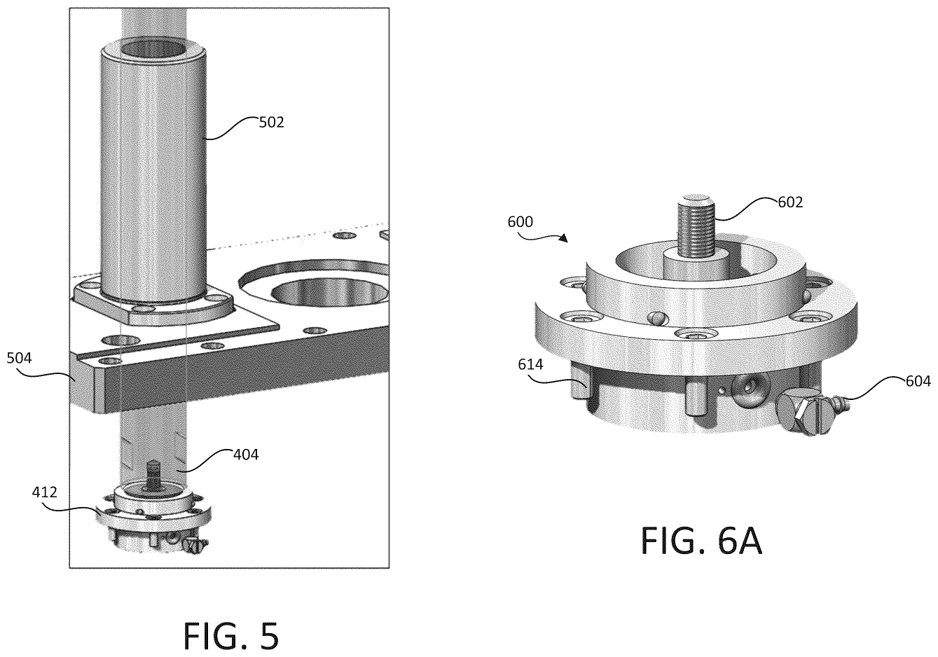

Following the thermal staging area 110, the carriers 108 can rotated into the testing station 116 (also referred to as a “testing chamber”) by the carrier retainer disks 109, where the DUTs undergo electrical testing. The testing station 116 can include contactors that can create an electrical connection while physical contact is made between the contactors and input/output (“I/O”) points of the DUTs (e.g., I/O contact pins, I/O contact pads, and/or the like on the DUTs). The testing station 116 may apply a testing signal to the DUTs. For example, the testing station 116 can apply electrical power or current to the DUTs via the contactors. The testing station 116 can measure one or more parameters of the DUTs during testing. For example, the testing station 116 can measure changes in temperature of the DUTs, output power of the DUTs, and/or other parameters in response to the applied testing signal. The testing station 116 may lock the position of the coupons and/or the position of the DUTs in the coupons, removing any freedom of movement the coupons and/or DUTs within the coupon have during testing. In some implementations, the testing station 116 can include an active thermal control (“ATC”) system that can raise and/or lower temperature of the DUTs during testing. A portion of an example testing station 116 is illustrated in FIG. 5A.

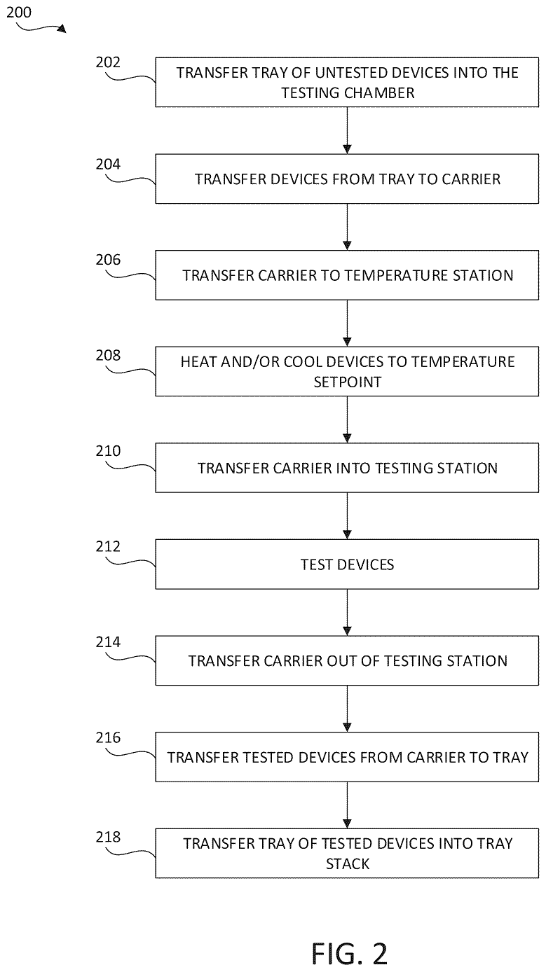

FIG. 2 is an example process 200 of testing DUTs using an electronic device testing system 100, according to various embodiments. Process 200 may contain more, or fewer, steps than illustrated in FIG. 2. Some of the steps of process 200 may be repeated. Further, the steps of process 200 may be performed in other orders than those illustrated in FIG. 2.

At block 202, the electronic device testing system 100 transfers a tray of untested devices or DUTs into the thermal chamber 102. For example, the TPS 106 may use a tray frame to carry a tray of untested devices from the tray stacks 104 into the thermal chamber 102. At block 204, the electronic device testing system 100 transfers devices from the tray into one or more carriers 108. For example, the input station 107 may carry individual ones of the devices from the tray and place them into coupons on the carriers 108. In some implementations, the tray may have a larger number of devices than can be held in a carrier 108. In these implementations, the devices in the tray may be loaded into multiple carriers 108. In other implementations, the tray may have a smaller number of devices than can be held in a carrier 108. In these other implementations, the electronic device testing system 100 may load multiple trays of untested devices into a single carrier 108.

At block 206, the electronic device testing system 100 transfers a carrier 108 into the thermal staging area 110. For example, a carrier retainer disk 109 can rotate the carrier 108 into the thermal staging area 110. In some embodiments, the carrier 108 may be placed in one or more stacks of carriers 108 within the thermal staging area 110.

At block 208, the devices in the carrier 108 are heated and/or cooled to a temperature setpoint within the thermal staging area 110. For example, the thermal staging area 110 may use convection, radiation, and/or other heating processes to heat the devices. As another example, the thermal staging area 110 may use cold gases, heat sinks, and/or other cooling processes to cool the devices. The thermal stating area 110 may also control pressure and/or moisture of its atmosphere. It will be appreciated that, in some embodiments, no heating or cooling may occur, e.g., where the devices are tested at room temperature. At block 210, the carrier 108 is transferred into the testing station 116. For example, the carrier retainer disk 109 can rotate the carrier 108 into the testing station 116.

In some implementations, the carrier 108 may be in the thermal staging area 110 for multiple testing cycles. The thermal staging area 110 can include multiple stations for setting and soaking the temperature of the devices. For example, the thermal staging area 110 can include two stations, three stations, or more stations for setting and soaking the temperature of the DUTs. In some of these implementations, the electronic device testing system 100 may stack carriers 108 in the thermal staging area 110. For example, as the carrier 108 is transferred to the thermal staging area 110 at block 206, the carrier 108 can be removed from the carrier retainer disk 109 and added to the stack. The electronic device testing system 100 may remove the carriers 108 from a stack one by one as they are rotated out of the thermal staging area 110. For example, as a carrier 108 is transferred to the testing station 116 at block 210, the carrier 108 can be removed from a stack and placed on a carrier retainer disk 109 and rotated by the carrier retainer disk 109 into the testing station 116. In some implementations, the devices may not be subjected to heat or cold treatments. In these implementations, the electronic device testing system 100 may cause a carrier 108 to bypass the thermal staging area 110. For example, the carrier 108 may not be added to a stack and continued to be carried through the thermal staging area 110. As another example, the thermal staging area 110 may be omitted in some implementations. In some implementations, carriers 108 are singulated from the stack and transferred to the testing station 116.

At block 212, the electronic device testing system 100 tests the devices. The electronic device testing system 100 may move the carrier and/or contactors of the testing station 116 such that the contactors make physical contact I/O points of the devices. The testing station 116 may lock the devices into a position in the coupons and/or lock the position of the coupons in the carrier. The testing station 116 may apply a test signal, e.g., a load, to the devices and measure one or more parameters on the devices in response to the test signal. The electronic device testing system 100 may record the results of the test for each device, such as the parameter values, and associate the results with the device.

At block 214, the electronic device testing system 100 transfers the tested devices out of the testing station 116. For example, the electronic device testing system 100 can move the carrier back onto a carrier retainer disk 109 and rotate the carrier retainer disk out of the testing station 116. At block 216, the electronic device testing system 100 transfers the tested devices from the carrier 108 to one or more trays. For example, the output station 118 may carry the tested devices from the coupons of the carrier 108 to the tray. At block 218, the electronic device testing system 100 transfers the tray of tested devices into the tray stacks 104. For example, the TPS 106 may carry a tray of tested devices from the thermal chamber 102 to the tray stacks 104. In various implementations, the electronic device testing system 100 may index and track the devices throughout process 200. For example, the electronic device testing system 100 may index the devices as they are transferred into the thermal chamber 102 and associate the results of the test with the indexed devices, such that as the devices are transferred into the trays and out of the thermal chamber 102, each individual device and test result are known for each position of the device in the tray.

According to various embodiments of the process 200, once the DUTs are individually transferred to a carrier using the PnP head, the DUTs are transferred within the system 100 (FIGS. 1A-1C) through usage of the carriers 108, without handling DUTs out of the carriers 108 as the DUTs are transferred though different stations. For example, blocks 206-214 above may be performed without removing the DUTs from the carriers 108. Unlike existing methods, once the DUTs are transferred 202 onto the carriers 108, the station-to-station transfers and testing of the DUTs are performed without removing them from the carriers 108, which greatly reduces device displacement events, as there may not be a need for handling the DUTs using, e.g., vacuum handlers. Until after the testing is completed. The reduced handling of the DUTs greatly reduces the probability of displacing the DUTs, which has traditionally been one of the biggest throughput limiters of IC testing.

### Alignment System

Aspects of this disclosure relate to an alignment system for adjusting an alignment between components of an electronic device testing system, such as the electronic device testing system 100. According to various embodiments, the alignment system can include one or more alignment assemblies for facilitating alignment adjustments. An alignment assembly can include a metal (e.g., disposed in a metal reservoir) having a composition such that it has a solidus temperature within the service temperature range for testing IC devices (e.g., a room temperature). The metal in the alignment assembly can be liquified (e.g., by heating the metal) to adjust hardware components for positioning the DUT in preparation for testing and solidified (e.g., by cooling the liquid state metal and/or by halting the application of heat to the liquid state metal) to lock-in the position of the hardware components once the DUT is aligned. According to various embodiments, a DUT is aligned when the position of the DUT allows for proper testing of the DUT. For example, a DUT my be aligned based on one or more success criteria. Examples of success criteria can include an electrical feedback indicating pins of a contactor are carrying a signal, surfaces of the DUT and contacting components (e.g., s plunger heads or contactors) are parallel or substantially parallel, forces applied on the DUT from contacting components are evenly applied across surfaces of the DUT, and/or other suitable criteria. When the metal in the alignment assembly is in a liquid state, an alignment between components attached to the alignment assembly can be adjusted. When the metal in the alignment assembly is in a solid state, the alignment between the components attached to the alignment assembly is fixed in place. While the alignment system can be used throughout the electronic device testing system 100, for convenience, the alignment system will be described in context of a use in the testing station 116.

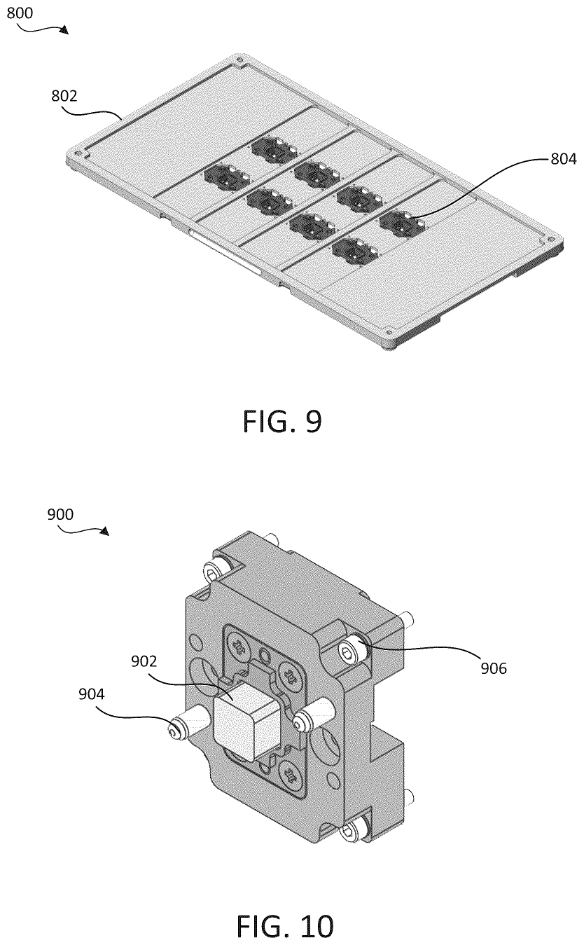

FIG. 3 illustrates a block diagram of a device test equipment 300) according to various embodiments. In some embodiments, the device test equipment may be used in the testing station 116. In the illustrated example, the testing station 116 includes a socket layout kit (“SLK”) 302, a carrier assembly 800, and a loadboard 1000. The carrier assembly 800 (described in more detail with respect to FIG. 9) can include one or more DUTs being tested in the testing station 116. The loadboard 1000 (described in more detail with respect to FIG. 12) can include contactors used to apply electrical power or current to the DUTs on the carrier assembly 800. The SLK 302 can include one or more components configured to interact with the DUTs being tested, such as plunger configured to apply a force to the DUTs, thermal heads configured to heat and/or cool the DUTs, sensors, other suitable components, and/or any combinations thereof.

In some embodiments, The SLK 302 is positioned on a first side of the carrier assembly 800 and the loadboard 1000 is positioned on a second side of the carrier assembly, opposite the first side. During testing of the DUTs, the SLK 302 (and/or components thereof) may apply force in direction Y on a first side of the carrier assembly 800 (and/or the DUTs on the carrier assembly 800) and the loadboard 1000 (and/or components thereof) may apply force in the direction Y′ on a second side of the carrier assembly 800 (and/or the DUTs on the carrier assembly 800), opposite the first side, establishing electrical contact between contactors of the loadboard 1000 and the DUTs and physical and/or thermal contact between components of the SLK 302 and the DUTs.

Misalignment in the testing station 116 can create several issues. For example, misalignment may prevent proper electrical contact between some of the DUTs in the carrier assembly 800 and the contactors of the loadboard 1000. As another example, misalignment between the SLK 302 and the carrier assembly 800 may prevent proper physical and/or thermal contact between components of the SLK 302 and the DUTs in the carrier assembly 800. In some instances, misalignment in the testing station 116 may cause the DUTs to become damaged, displace DUTs from the carrier assembly 800, compromise a test being performed, and/or cause additional issues. To mitigate such issues, alignment within the testing station 116 may be periodically calibrated and adjusted. For example, the alignment within the testing station may be calibrated at the start of each day, when the electronic device testing system 100 is first used to test a batch of DUTs, before a series of measurements, or in response to detection of a misalignment, to list a few instances. The alignment system described herein may be used to calibrate and/or adjust the alignment within the testing station 116. In some embodiments, when the SLK 302, carrier assembly 800, and loadboard 1000 are aligned or in a position of electrical testing of DUTs included on the carrier assembly 800, the surface of SLK 302 components (e.g., plungers configured to contact the DUTs) can be substantially parallel to a surface of contactors on the loadboard 1000.

In some embodiments, an aligner, such a carrier assembly 800 with alignment DUTs may be inserted into the testing device test equipment 300 during alignment operations, such the alignment described herein with respect to FIGS. 4A-4E, 5, and/or 6A-6C. An alignment DUT may be a “dummy” DUT that may be used for alignment purposes.

FIGS. 4A-4E illustrate an alignment system 400 used in a testing system 116, according to various embodiments. FIGS. 4A and 4B illustrate perspective views of the alignment system 400. FIG. 4C illustrates a front view of the alignment system 400. FIG. 4D illustrates a side view of the alignment system 400. FIG. 4E illustrates a perspective view of the alignment system 400 with a transparent housing 410. The alignment system 400 includes a housing 410 (FIG. 4B), one or more alignment assemblies 412 (FIG. 4E), a floating joint 414, and pillar connectors 416 (FIG. 4B). While FIGS. 4A-4E may illustrate specific number of some components (e.g., four pillar connectors 416 and two alignment assemblies 412), other numbers may be used. In some embodiments, some illustrated components may not be used.

In the illustrated embodiment, the alignment system 400 is physically coupled to a press assembly 402 (FIG. 4A) by guide shafts 404 (FIG. 4A) and floating shaft 406 (FIG. 4A). The guide shafts 404 are physically coupled to the alignment assemblies 412 and the 402 is physically coupled to the floating joint. The alignment system 400 is physically coupled to a SLK mount plate 408 (FIG. 4A) by SLK supports 409 (FIG. 4A). The SLK supports 409 are physically coupled to the pillar connectors 416 and the SLK mount plate 408. In some embodiments, the press assembly 402 applies a force such that components of the SLK (e.g., plungers, thermal heads, and/or other components) contact a DUT and/or a carrier, as discussed above. The alignment system 400 can adjust an alignment such that the force is properly applied and to correct for misalignments and associated issues described above.

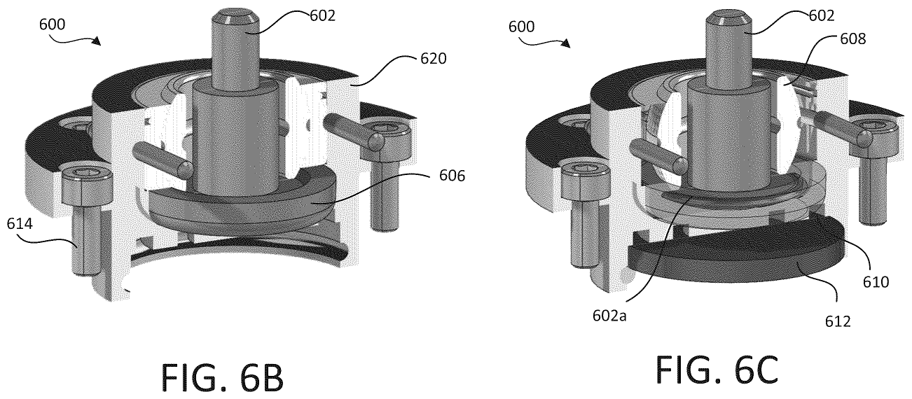

In some embodiments, the housing 410 may have a fixed alignment relative to the SLK mount plate 408. For instance, the SLK supports 409 may be rigidly coupled to the SLK mount plate 408 and the pillar connectors 416. Adjustments to the alignment of the alignment system 400 may also adjustment the alignment of the SLK mount plate 408 and a SLK (e.g., SLK 302) attached to the SLK mount plate 408. The alignment assemblies 412 which are shown in more detail in FIGS. 6A-6C, can provide for such adjustments.

The alignment assemblies 412, can have first portions that are rigidly fixed (e.g., permanently fixed or temporarily fixed using one or more fasteners) to the housing 410. The alignment assemblies 412 can be have second portions rigidly fixed (e.g., permanently fixed or temporarily fixed) to the guide shafts 404. In some implementations, the alignment assemblies 412 can have a fixed state and a free state. In the fixed state, the relative position of an the first portions of the alignment assembly 412 and the second portions of the alignment assembly can remain constant, even when force is applied to either the alignment assembly 412 and/or the guide shaft 404. Accordingly, when the alignment assemblies 412 are in the fixed state the relative position of the housing 410 and the shafts 404 is fixed. In the free state, the relative position of the first portion of the alignment assembly 412 and the second portion of the alignment assembly can have one or more degrees of freedom of motion and move in response to an applied force. In some embodiments, the relative position of the first portion of the alignment assembly 412 and the second portion of the alignment assembly 412 has six degrees of freedom of motion (e.g. three translational degrees of freedom and three angular degrees of freedom) when the alignment assembly 412 is in a free state. Accordingly, when the alignment assemblies are in a free state the relative position of the housing 410 and the shafts 404 have one or more degrees of freedom.

As described herein with respect to FIGS. 6A-6C, in some embodiments the alignment assemblies 412 can include a metal. When the metal of an alignment assembly 412 is liquified, the alignment assembly 412 can be in the free state and the positions of the alignment assembly 412, and/or components thereof, can be altered. When the metal of the alignment assembly 412 is solidified, an alterations to the positions of the alignment assembly 412 can be locked into place.

An opposing end of the guide shafts 404 can be fixed within the press assembly 402, such that the when the positional adjustments described above are made to the alignment assembly 412, the guide shafts 404 maintain a position relative to the press assembly 402. The floating shaft 406 can physically couple an actuator 403 of the press assembly 402 and the floating joint 414. The actuator 403 can be a linear actuator capable of applying force in a direction. The actuator 403 can apply the force through the floating shaft 406 and into the floating joint 414. From the floating joint 414, the force can travel through the housing 410, the SLK supports 409, the SLK mount plate 408, and into an attached SLK such that the SLK (and/or components of the SLK) interact with a carrier and DUTs on the carrier. The floating joint 414 can have some degrees of freedom relative to the floating shaft 406. As such, when positional adjustments are made by the alignment assemblies 412, the floating joint 414 can compensate. This compensation by the floating joint 414 can reduce forces in other directions (e.g., torsion forces) from being applied between the actuator 403 and an SLK attached to the SLK mount plate 408.

In some embodiments, the force applied by the actuator 403 is not transferred (or very little is transferred) to the connection points between the alignment assemblies 412 and the guide shafts 404. In some instances of these embodiments, only a torsion force effects the connections points between the alignment assemblies 412 and the guide shafts 404. Such a torsion force may be a result of an orientation of the SLK mount plate 408 relative to the direction of the force applied by the actuator 403. This reduction of force can reduce the stress placed on the alignment assemblies 412 (e.g., the metal within the alignment assemblies) and misalignments that may occur from said stress.

FIG. 5 illustrates a connected alignment assembly 412 and guide shaft 404, according to an embodiment. The guide shaft 404 is positioned in a guide sleave 502 and fixed plate 504 of the press assembly 402. As the alignment assembly 412 and the guide shaft 404 move (e.g., in response to the actuator 403 applying a force), the guide sleave 502 and fixed plate 504 remain in the same position.

FIGS. 6A-6C illustrate an alignment assembly 600 according to various embodiments. In some embodiments, the alignment assembly 600 can be used as the alignment assembly 412 of FIGS. 4A-4E. FIG. 6A illustrates a perspective view of the alignment assembly 600, FIG. 6B illustrates a perspective of a cross section of the alignment assembly 600 with a heater not shown, and FIG. 6C illustrates a perspective of a cross section with a heater shown and a metal transparent. In the illustrated example, the 600 includes a anchoring shank 602, a cooling inlet 604 (FIG. 6A), fasteners 614 (FIGS. 6A, 6B), metal 606 in a metal reservoir (FIG. 6B), a ball bearing 608 (FIG. 6C), an alignment housing 620 (FIG. 6B), a heater 612 (FIG. 6C), and cooling channels 610 (FIG. 6C).

In some embodiments, the alignment assembly 600 can be used to adjust an alignment of a first connected component (e.g., the guide shafts 404 of FIGS. 4A-4E) and a second connected component (e.g., the SLK supports 409 of FIGS. 4A-4E) and to lock the alignment in place. In the illustrated embodiment, the alignment assembly 600 is configured to operate in the alignment system 400 (e.g., as an alignment assembly 412).

The anchoring shank 602 may couple the alignment assembly 600 to the first connected component (e.g., a shaft 404). In some embodiments, linear motion may be applied on the alignment assembly 600 via the anchoring shank 602 from the shafts 404. The fasteners 614 may couple the alignment assembly 600 to the second connected component (e.g., the housing 410). The alignment assembly 600 can have a locked state where the alignment of the first connected component and the second connected component is fixed (e.g., a relative position of the first and second connected components is restricted by one or more degrees of freedom of motion). The alignment assembly 600 can have a free state where the alignment of the first connected component and the second connected component is not fixed (e.g., a relative position of the first and second connected components has one or more degrees of freedom of motion). In some embodiments, when the alignment assembly 600 is in a free state, a relative position of the first and second connected components is movable with six degrees of freedom.

The physical state of the metal 606 can determine whether the alignment assembly 600 is in a locked state or a free state. For instance, when the metal 606 is in a liquid state (e.g., the metal 606 is molten), the alignment assembly 600 is in a free state and the relative position of the first and second connected components is movable. When the metal 606 is in a solid state, the alignment assembly 600 is in a locked state and the relative position of the first and second connected components can be fixed (e.g., the position of the alignment assembly may be lock-in). The metal 606 may be mechanically coupled to the alignment assembly 600 (e.g., the anchoring shank 602 and/or the fasteners 614). In various embodiments, the alignment assembly 600 can include two general portions. The first portion can include components (e.g., the anchoring shank 602 and anchoring member 602a) that have a fixed position relative to the first connected component (e.g., the shafts 404). The second portion can include components (e.g., the alignment housing 620 and fasteners 614) that have a fixed position relative to the second connected component (e.g. the housing 410). When the metal 606 is in a liquid state, the first portion and the second portion of the alignment assembly 600 may be free to move with respective to other (e.g., has one or more degrees of freedom of motion). When the metal 606 is in a liquid state, the first portion and the second portion of the alignment assembly 600 may by fixed respective to the other.

According to various embodiments, the metal 606 has a eutectic composition or about a eutectic composition. Because at eutectic composition, the metal undergoes a liquid-solid phase transition abruptly, the position of components coupled thereto can be frozen in relatively accurately. If the metal is substantially outside of the eutectic composition, the relatively gradual phase transition may allow for the components coupled thereto to move out of alignment during the transition. As such, the eutectic composition can improve the consistency of the alignment assembly 600. According to various embodiments, the composition of the metal can have one or more of the constituent elements within 1 weight %, 2 weight %, 3 weight %, 4 weight %, 5 weight % or a value in a range defined by any of these values, of the eutectic composition.

The metal 606 can have a relatively low melting temperature (e.g., a solidus temperature). For example, the eutectic composition of the metal 606 can have a solidus temperature within 20° C., 15° C., 10° C., 5° C., 3° C., 2° C., 1° C. or a value in a range defined by any of these values, of the eutectic temperature. The eutectic melting temperature can be between room temperature and about 100° C., between about 40° C. and about 80° C., or about 55° C. and about 65° C. or another suitable temperature. The metal 606 can have a solidus temperature above a room temperature (e.g., an ambient temperature of the device test equipment 300).

The metal 606 may have a suitable composition to achieve the eutectic melting temperature. In some embodiments, the metal 606 includes bismuth (Bi), lead (Pb), indium (In), tin (Sn), and cadmium (Cd). For example, the metal 606 may be comprised of a composition with 40-50 weight % Bi, 18-28 weight % Pb, 14-24 weight % In, 3-13 weight % Sn, and 1-6 weight % Cd, for instance a composition of 51 percent indium (In), 32.5 percent bismuth (Bi), and 16.5 percent tin (Sn). In another example, the metal 606 may be comprised of a composition with 45-55 weight % Bi, 22-32 weight % Pb, 8-18 weight % Sn, and 5-15 weight % Cd. In some embodiments, the metal 606 includes Bi, In, Pb, and Sn. For example, the metal 606 may be comprised of a composition with 44-54 weight % Bi, 16-26 weight % In, 13-23 weight % Pb, and 7-17 weight % Sn, for instance a composition of 44.7 percent bismuth (Bi), 22.6 percent lead (Pb), 19.1 percent indium (In), 8.3 percent tin (Sn), and 5.3 percent cadmium (Cd). In some embodiments, the metal 606 includes In, Bi, and Sn. For example, the metal 606 may be comprised of a composition with 46-56 weight % In, 28-38 weight % Bi, and 11-21 weight % Sn, for instance a composition of 49 percent bismuth (Bi), 21 percent indium (In), 18 percent lead (Pb), and 12 percent tin (Sn). For instance,, the metal 606 has a composition of 50 percent bismuth (Bi), 26.7 percent lead (Pb), 13.3 percent tin (Sn), and 10 percent cadmium (Cd). However, any suitable composition may be used for the metal 606 that exhibits similar attributes. In some embodiments, aside from unavoidable impurity levels (e.g. 0.1 weight %, 0.001 weight %, 0.0001 weight %, or less), the metal 606 may be essentially free of Cd. In some embodiment, the metal 606 may be essentially free of Pb. In each of these compositions, the elements including incidental impurities can add up to 100%.

According to various embodiments, the heater 612 can heat the metal 606 above the melting temperature of the metal 606. For example, the heater 612 can be adjacent to the metal 606 and/or thermally coupled to the metal 606. The heater 612 can be any suitable heater such as a restive or inductive heater. In some embodiments, the heater can include sensors, such as resistance temperature detectors (“RTDs”) that can be used to determine a temperature of the metal 606 and/or the heater 612. The heater 612 can be connected to a heater control circuit configured to activate the heater 612 such that the metal 606 is liquified. The heater control circuit can deactivate the heater 612 such that the metal 606 solidifies. In some embodiments, the alignment assembly 600 does not include a heater. For example, the alignment assembly 600 may utilize heated gasses resulting from other operations in the electronic device testing system 100 to heat the metal 606. The cooling inlet 604 and the cooling channels 610 may be used to facilitate the heated gasses rather than, or in addition to, the cooling functionality described herein.

In some embodiments, the ambient temperature of the alignment assembly 600 is below the melting point temperature of the metal 606 such that once the heater 612 deactivates, the metal 606 will resolidify. The cooling channels 610 can increase the rate at which the metal 606 cools below the melting point. In some embodiments, a coolant, such as clean dry air (CDA), can be injected into the cooling channels 610, via the cooling inlet 604. The coolant can be used to increase the rate the metal 606 solidifies. The coolant can be injected into the cooling channels 610 based on a control signal and/or a determination that an alignment process has been completed.

As illustrated in FIGS. 6B and 6C, the anchoring shank 602 contacts the metal 606. When the metal 606 is in a liquid state, the anchoring shank 602 can move with six degrees of freedom within the alignment assembly 600 (e.g., relative to the alignment housing 620). In some embodiments, the anchoring shank 602 can have less than six degrees of freedom within the alignment assembly 600. In some embodiments the alignment assembly 600 has at least a vertical translational degree of freedom with the metal 606 is in a liquid state. When the metal 606 is in a solid state, the anchoring shank 602 is fixed within the alignment assembly 600.

In some embodiments, the anchoring shank 602 pin can be partially submerged in the metal 606. The anchoring shank 602 can include an anchoring member 602a attached at the end. In the illustrated embodiment the anchoring member 602a is a disk having a widened diameter relative to the main shaft portion of the anchoring shank 602. However, embodiments are not so limited and other suitable forms may be used for the anchoring member 602a. The anchoring member 602a can increase the surface area of the anchoring shank 602 that contacts the metal 606. Further, portions of the metal 606 to fluidically surround the anchoring member 602a. The anchoring member 602a having the widened portion can provide higher resistance to motion when the metal 606 is in a viscous liquid state. As such, the anchoring member 602a can increase the stability of the anchoring shank 602 when the metal 606 is in a solid state, which can help prevent displacement of the anchoring shank 602 in solidified metal 606 in the presence of force (e.g., a torsion force). In the illustrated embodiment, an end portion of the anchoring shank 602 such as the anchoring member 602a is submerged in the metal 606. However, embodiments are not so limited and in other embodiments, the end portion can be partly submerged or in contact with the metal 606. In the illustrated embodiment, the alignment assembly 600 includes a ball bearing 608. The ball bearing 608 can provide further stability for the anchoring shank 602, both when the metal 606 is solid and when the metal 606 is liquid.

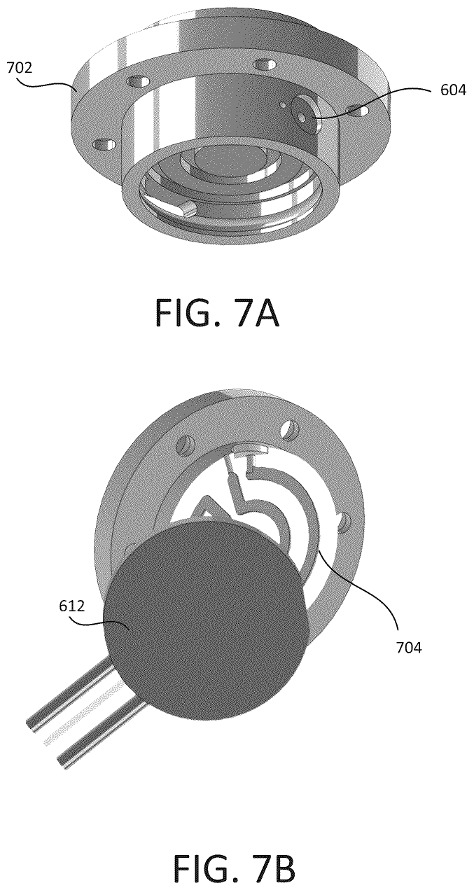

FIGS. 7A and 7B illustrate aspects of heating and cooling the metal 606 in an alignment assembly 600 according to various embodiments. The temperature control portion 702 of the alignment assembly 600 may define a heating and cooling chamber of the alignment assembly 600. The heating and cooling chamber can have space for the cooling channels 610 and the heater 612. The temperature control portion 702 can have openings (e.g., cooling inlet 604) to facilitate the flow of coolant and/or allow space for electrical leads of the heater 612. The temperature control portion 702 can have a heater contact surface 704 that transfers heat from the heater 612 to the metal 606. In some embodiments, the cooling channels 610 are embedded within and/or formed by the heater contact surface 704 and the heater contact surface 704 can aid in cooling the metal 606 when the heater 612 is off. By active cooling, the metal 606 can be solidified quickly and reduce alignment time.

### Example Alignment Process

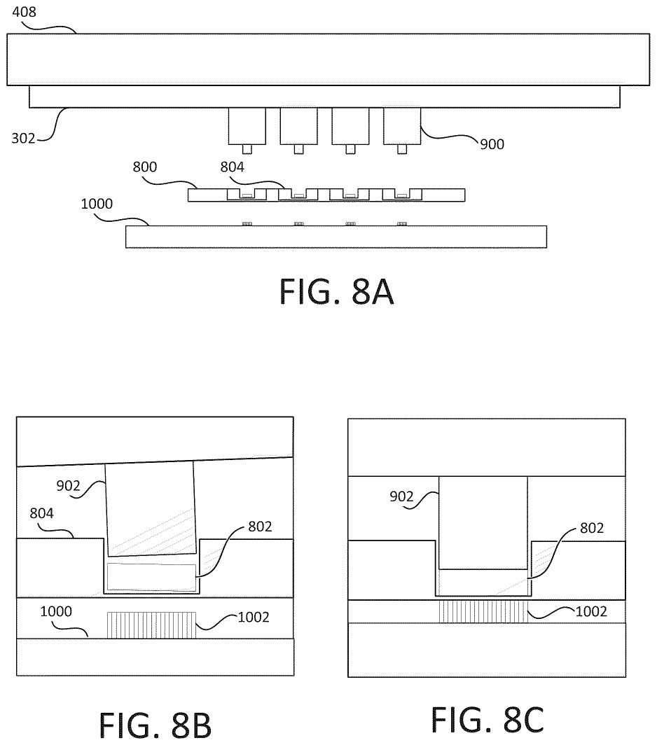

FIGS. 8A-8C illustrate an example process of aligning an SLK 302 and plunger assembly 900, a DUT 802, and contactors 1002. FIG. 8A illustrates a general position of an SLK 302 (with plunger assemblies 900), a carrier assembly 800 (with coupons 804 holding DUTs), and a loadboard 1000 (with contactors). The SLK 302 is mechanically coupled to a SLK mount plate 408 an, by extension, the alignment system 400 (FIGS. 4A-4E) and includes plunger assemblies 900 (described in more detail with respect to FIG. 10). As described herein, the alignment system 400 allows for the relative position of the SLK mount plate 408 (and by extension the SLK 302) to be adjusted (e.g., when the metal 606 is in a liquid state). As such, the SLK 302 can be adjusted relative to the carrier assembly 800 and loadboard 1000.

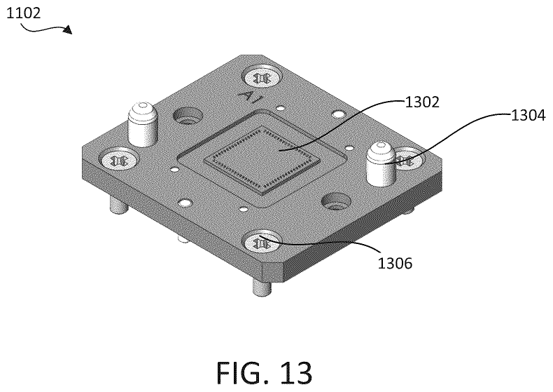

The carrier assembly 800 (described in more detail with respect to FIG. 9), includes coupons 804 with DUTs 802 held therein. The loadboard 1000 (described in more detail with respect to FIG. 12) includes contactors 1002 (described in more detail with respect to FIG. 13). During testing, a DUT 802 makes contact with a plunger 902 of the plunger assembly 900 on a first side and a contactor 1002 on a second side, opposite the first side. If the plunger 902, the DUT 802, and/or the contactor 1002 are misaligned, the test may be compromised (e.g., unreliable or fail altogether), the DUT 802 may be damaged, and/or other issues may occur.

FIGS. 8B and 8C illustrate an example of aligning the plunger 902, the DUT 802, and the contactor 1002 according to various embodiments. In FIG. 8B, an alignment between a DUT 802 and a plunger 902 (e.g., of a plunger assembly 900) is off. In the illustrated embodiment, the surface of the plunger 902 is not parallel to the surface of the DUT 802. As such, if no adjustment occurs, when the plunger 902 makes contact with the DUT 802 for testing, the plunger 902 will apply force unevenly on the DUT 802. In FIG. 8C, the alignment between the DUT 802 and plunger 902 has been corrected. In the illustrated embodiment, the surface of the plunger 902 that contacts the DUT 802 is parallel (or substantially parallel) to a surface of the DUT 802. As such, force applied by the plunger 902 is even across the surface of the DUT 802.

According to various embodiments, an alignment system 400 may facilitate the correction of the alignment. At a first step, prior to the plunger 902 contacting the DUT 802, an alignment assembly 600 of the alignment system 400 may enter a free state. For example, the metal 606 can be liquified (e.g., through the application of heat) causing the alignment assembly 600 to enter the free state. At a second step, while the alignment assembly 600 is in a free state, the SLK mount plate 408 may be lowered (e.g., by the actuator 403) such that the plunger 902 contacts the DUT 802 at a first side and applies force on the DUT 802. As the alignment assembly 600 is still in a free state, the relative alignment of the plunger 902 and the DUT 802 can be adjusted. Accordingly, as the plunger 902 and the DUT 802 engage, the force of the interaction applied on the plunger 902 can realign the alignment assembly 600 (e.g., adjust the relative position of the first portion and second portion of the alignment assembly 600) and the surface of the plunger 902 and the DUT 802 can become parallel.

In various embodiments, other adjustments may also occur. For example, the DUT 802 can have some freedom of movement within the coupon 804. In some embodiments, the DUT 802 has six degrees of freedom of movement within the coupon 804 prior to the DUT 802 engaging with the plunger 902 and/or the contactor 1002. Accordingly, while the alignment assembly 600 is in a free state, and as the plunger 902 applies a force on the DUT 802 on the first side, a contactor 1002 may begin to contact the DUT 802 on a second side opposite the first. These forces can also adjust the alignment of the DUT 802 and the contactor 1002.

At a third step, once the plunger 902 and the DUT 802 (and/or the contactor 1002) have been aligned (e.g., as illustrated in FIG. 8C), the alignment assembly 600 may enter a fixed state. For example, the metal 606 can be solidified (e.g., through halting the application of heat and/or through a cooling source) causing the alignment assembly 600 to enter the locked state. As such, the alignment of the plunger 902 and the DUT 802 (and/or the contactor 1002) is maintained, even as the force between them is removed. Accordingly, the 902 can be disengaged from the DUT 802 while maintaining an alignment (e.g., a surface of the plunger 902 and the first surface of the DUT 802 remains parallel). With the alignment set, the testing equipment can feed new batches of DUTs that maintain the same alignment.

FIGS. 8B and 8C illustrate a misalignment and alignment with respect to one degree of motion (e.g., rotation about a first lateral axis). However, other misalignments may also occur and be corrected in a similar manner described herein. In some embodiments, the alignment assembly 600 may be used to align with respect to five degrees of freedom of motion. For example, the alignment assembly 600 may be used to align with respect to three rotational axes and 2 transversal axes, the transversal axis that is not aligned by the alignment assembly 600 being propagated by the actuator 403 (e.g., Y and Y′ illustrated in FIG. 3).

In some embodiments, the alignment between the plungers 902 and DUTs 802 can be maintained throughout all, or a portion of the testing (e.g., through 10 batches, 100 batches, a day of testing, and/or other portions of the testing). In some embodiments, the alignment of the plungers 902 and the DUTs 802 is recalibrated after a set number of tests (e.g., 10 tests, 100 tests, a batch, 10 batches). In some embodiments, the alignment of the plungers 902 and the DUTs 802 is performed when the test equipment is initialized. In some embodiments, the alignment assembly 600 (or other component of the test equipment) can include sensors or other suitable devices that can determine with the alignment of the plungers 902 and the DUTs 802 is off. In some of these embodiments, the test equipment is set to automatically perform the alignment processes described herein with such a determination is made.

### Example Additional Components

FIG. 9 illustrates a perspective view of a carrier assembly 800 according to embodiments. In the illustrated embodiment, carrier assembly 800 includes a body 802 and one or more coupons 804. The body 802 has formed thereon a plurality of coupon pockets into which the coupons can be removably inserted. The pockets can be arranged in an array, e.g., an array of rows and columns. It will be appreciated that for illustrative purposes only, the illustrated carrier assembly 800 includes eight total coupons 804, arranged in two rows of four coupons 804. However, other numbers of coupons 804 and other arrangements of coupons 804 may be used. For example, eight coupons 804 may be arranged in in a single row of eight coupons 804. As another example, carrier assembly 800 may have a single coupon 804 or may have more than eight coupons 804 (e.g., 32 coupons 804). In some implementations, the coupons 804 are not arranged in rows.

Each coupon 804 is configured to house a device, such as a DUT. As such, the carrier assembly 800 may be used to carry one or more DUTs throughout a device testing system, such as the electronic device testing system 100 of FIGS. 1A-1C.

Among other functions, the body 802 can provide structural support for the coupons 804. The body 802 can allow the coupons 804 to be securely transported without removing the coupons 804. While placed in the coupon pocket, the coupon holding the DUT may have up to six degrees of freedom of movement within the coupon pocket, including three independent linear degrees of freedom and three independent angular degrees of freedom, until the DUT is secured for testing on a contactor. The degrees of freedom may be provided by an assembly of springs that loosely retain the coupons 804 within the coupon pockets. The degrees of freedom may allow the coupons to move within the carrier assembly 800 without damaging the DUT and/or dislodging the coupon from the carrier. As configured, the coupon pockets are dimensioned to accommodate movements of the coupons within the pockets in lateral and vertical directions within less than about 20%, 10%, 5%, 2%, or value in a range defined by any of these values, of corresponding lateral dimensions of the DUT.

The carrier assembly 800 may be placed in between an SLK and a loadboard. One or more alignment assemblies, such as the alignment assembly 600 may be used to facilitate and alignment between the SLK, the carrier assembly 800 (and/or the DUTs in the coupons 804), and other components of the testing system (e.g., an actuator applying force). In some embodiments, one more alignment assemblies may be used to align individual components of the SLK (e.g., plungers, plunger assemblies, and/or thermal heads) to DUTs in the coupons 804.

In some embodiments, the carrier assembly 800 may be used to facilitate the alignment of the testing system 116. For example, prior to testing, a carrier assembly 800 may be placed in the testing station 116 and engaged with an SLK and loadboard. While the carrier assembly 800 is engaged with the SLK and loadboard, one or more alignment assemblies 600 (e.g., alignment assemblies 600 mechanically coupled to SLK and/or the DUTs in the carrier assembly 800) may be adjusted. For example, metal 606 within the alignment assemblies 600 may be liquified, allowing the alignment assemblies 600 to move with respect to one or more degrees of freedom of motion based on an alignment with the carrier assembly 800 and/or DUTs in the carrier assembly 800. The metal 606 within the alignment assemblies 600 may be solidified, locking in the adjustments. In some embodiments, the carrier assembly 800 may contain placeholder aligners (also referred to as “aligners”) in the coupons 804 rather than DUTs for this aligning process. The placeholder aligners may align the alignment assemblies 600 to a proper alignment without running DUTs through the electronic device testing system.

FIG. 10 illustrates a plunger assembly 900 (also referred to as a “nest” or a “thermal head”) according to various embodiments. The plunger assembly 900 may be used to apply a force on a coupon 804 and/or a DUT to make contact therewith. The plunger assembly 900 may displace a coupon 804 relative to a body 802 of a carrier assembly 800 during testing of one or more DUTs. In the illustrated embodiment, the plunger assembly 900 includes a plunger 902, alignment pins 904, and fasteners 906.

The plunger 902 may be configured to be inserted into a DUT pocket of a coupon 804. The plunger 902 may contact the DUT and apply a force on the DUT, such that the DUT has restricted movement in at least a vertical axis, e.g., a z direction. In some embodiments, the force may be originated in an actuator, such as actuator 403 illustrated in FIG. 4A.

The alignment pins 904 may help ensure alignment between the DUT pocket and the plunger 902. The alignment pins 904 may prevent the coupon 804 from moving laterally, e.g., in x and y directions, with respect to the plunger assembly 900. The fasteners 906 may couple the plunger assembly 900 to a component of a testing station, such as an SLK that is connected to the SLK mount plate 408. The fasteners 906 can include screws, rivets, pins, and/or other fasteners.

In some embodiments, the plunger assembly 900 may be a component of an active thermal control (ATC) system that can raise and/or lower temperature of the DUTs during testing. The ATC system may provide or carry away heat using one or more heat exchangers coupled to heat and/or cold sources. For example, the plunger assembly 900 may include one or more heat sinks in thermal connection with a cooling source (e.g., a refrigerant, cold gasses, liquid nitrogen, compressed clean dry air (CDA), and/or other cooling source). The DUT may undergo thermal change during testing. For example, a test signal, or other electrical signal provided to the DUT, may cause a temperature of the DUT to rise. As another example, the temperature of the DUT may fall naturally and/or fall due to exposure to the one or more heat sinks. In these embodiments, the ATC system can utilize the plunger assembly 900 to alter and/or maintain the temperature of the DUT at a desired level (e.g., a testing temperature). In some implementations, the amount of heat provided to the DUT may be actively adjusted, e.g., offset, based on the amount of power delivered to the DUT as part of the testing signal. As configured, the coupon 804 (FIG. 9) having a top opening configured to receive a plunger for ATC during testing, and having the access openings at the bottom configured for electrical contacts with a contactor for sending and receiving electrical test signals can be particularly suitable for testing logic devices such as microprocessors that may dissipate a large amount power, some of which dissipates as heat, which can exceed over 100 W, 200 W, 500 W, 1000 W, 2000 W, or a value in a range defined by any of these values.

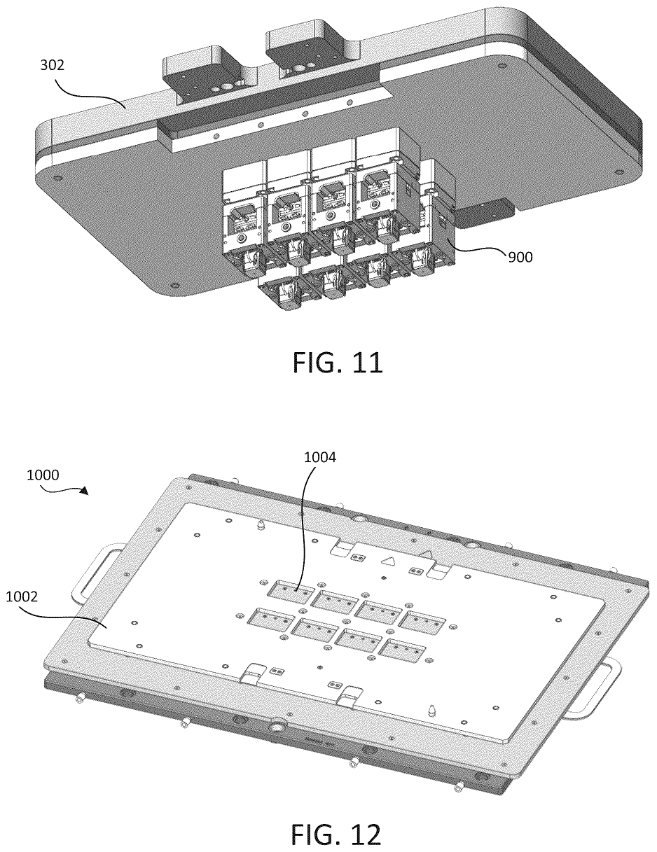

FIG. 11 illustrates an example SLK 302 according to various embodiments. In the illustrated example the SLK 302 thermal heads of the plunger assemblies 900 are exposed. In some embodiments the thermal heads may be disposed, at least partially, in a component, such as a nest plunger.

According to various embodiments the SLK 302 can include various suitable fastening components and be mechanically coupled to the SLK mount plate 408 (FIG. 4A). Accordingly, as the alignment assembly 412 are adjusted, the SLK 302 and the plunger assemblies 900 may also be adjusted (e.g., aligning the plunger assemblies 900 with DUTs 802).

FIG. 12 illustrates a loadboard 1000 (also referred to as a “socket support frame”) according to various embodiments. The loadboard 1000 may be part of a testing station, such as testing station 116. The loadboard 1000 may be configured to raise one or more sockets, such that the sockets temporarily couple to a coupon 804 in a carrier assembly 800. In the illustrated embodiment, the loadboard 1000 includes a plate 1002 with a plurality of socket ports 1004.

Each socket port 1004 may be configured to couple to a socket. The number and arrangement of socket ports 1004 may depend on the number and arrangements of coupons 804 in a carrier assembly 800. For example, FIG. 12 illustrates eight total socket ports 1004, arranged in two rows of four socket ports 1004, matching the arrangement of coupons 804 in the carrier assembly 800, illustrated in FIG. 9. However, other numbers and arrangements of socket ports 1004 may be used to match other numbers and arrangements of coupons 1004. In some embodiments, the 1002 may be replaced on the loadboard 1000 to accommodate a different number and arrangement of coupons 804 in a carrier assembly 800.

FIG. 13 illustrates a socket 1102 according to various embodiments. The socket 1102 may be used in testing a DUT held in a coupon, such as coupon 804. In the illustrated embodiment, the socket 1102 includes contactors 1302, alignment features 1304, and fasteners 1306. The contactors 1302 can be configured to contact the I/O ports of a DUT held in a coupon. For example, the contactors 1302 can include one or more electrical contacts, probes, and/or the like configured to establish an electrical connection with the I/P ports of a DUT. The contactors 1302 may be configured to deliver a test signal, e.g., a load, to the DUT.

The alignment features 1304 may be configured to be inserted into some, or all, of a plurality of holes of a coupon 804, providing a general alignment between the contactors 1302 and a DUT held by the coupon 804. In the illustrated embodiment, the alignment features 1304 are configured to be inserted into the holes at diagonal positions. The alignment features 1304 may help ensure alignment between the DUT and the contactors 1302.

In some embodiments the contactors 1302 and/or the alignment features 1304 may lock a coupon in place during testing (e.g., the testing position and in alignment with the contactors 1302). For instance, the contactors 1302 and/or the alignment features 1304 may remove one or more of the six degrees of movement of the DUT within a DUT pocket such that the DUT remains fixed in place during testing. The coupons may be allowed limited movement until the alignment features 1304 lock them in position for testing. The alignment features 1304 can provide a simple securing mechanism for precise positioning the DUTs without using complex mechanisms such as vacuum chucks. While alignment features 904, and alignment features 1304 are illustrated in various figures as having elongated cylindrical shapes, other features and shapes may be used to facilitate alignment and/or prevent lateral movement between the coupon 804 and the nest plunger 902 and/or between the coupon 804 and the socket 1102. For example, the coupon 804, the nest plunger 900, and/or the socket 1102 may include machined corresponding features (e.g., machined polygonal features such as rectangular or square features engaging with corresponding polygonal holes such as rectangular or square holes, machined oblong features engaging with corresponding oblong holes, or other suitable machined features, or any combination thereof).

The fasteners 1306 may couple the socket 1102 to a component of a testing station, such as the testing station 116. For example, in some implementations, the fasteners 1306 couple the socket 1102 to the loadboard 1000 illustrated in FIG. 12. The fasteners 1306 can include screws, rivets, pins, and/or other fasteners.

In some embodiments, the nest plunger 900 and/or the socket 1102 may be a component of an active thermal control (ATC) system configured for thermal management of the DUT during electrical testing. For example, the ATC system may raise and/or lower the temperature of the DUTs during testing. The ATC system may provide or carry away heat using one or more heat exchangers coupled to heat and/or cold sources. For example, the nest plunger 900 may include one or more heat sinks in thermal connection with a cooling source (e.g., a refrigerant, cold gases, liquid nitrogen, compressed clean dry air (CDA), and/or other cooling sources). The DUT may undergo thermal change during testing. For example, the test signal, or other electrical signal provided to the DUT by the socket 1102, may cause a temperature of the DUT to rise. As another example, the temperature of the DUT may fall naturally and/or fall due to exposure to the one or more heat sinks. In these embodiments, the ATC system can utilize the nest plunger 900 and/or the socket 1102 to alter and/or maintain the temperature of the DUT at a desired level (e.g., a testing temperature). In some implementations, the amount of heat provided to the DUT may be actively adjusted, e.g., offset, based on the amount of power delivered to the DUT as part of the testing signal. As configured, the coupon 804 (FIG. 9) having a top opening configured to receive a plunger for ATC during testing, and having the access openings at the bottom configured for electrical contacts with a contactor for sending and receiving electrical test signals can be particularly suitable for testing logic devices such as microprocessors that may dissipate a large amount power, some of which dissipates as heat, which can exceed over 100 W, 200 W, 500 W, 1000 W, 2000 W, or a value in a range defined by any of these values.

### Additional Examples

1. A method of positioning an alignment assembly of a device test equipment, the method comprising:
   providing the alignment assembly configured to align a device under test (DUT) for electrical testing, the alignment assembly mechanically coupled to a metal in a metal reservoir;
   adjusting the alignment assembly into a position for electrical testing of the DUT with the metal in a liquid state; and
   solidifying the metal to lock-in the position of the alignment assembly.
1. The method of Embodiment 1, wherein prior to adjusting, the metal is in a solid state in which the alignment assembly has one or more degrees of freedom of motion restricted, wherein the method further comprises, prior to adjusting, melting the metal into the liquid state to at least partly remove the restriction to the one or more degrees of freedom of motion.
2. The method of Embodiment 2, wherein melting comprises applying heat to the metal reservoir from outside the metal reservoir.
3. The method of Embodiment 3, wherein solidifying comprises stopping applying heat to the metal reservoir.
4. The method of Embodiment 3, wherein solidifying comprises actively cooling the metal reservoir.
5. The method of Embodiment 2, wherein solidifying comprises restricting the one or more degrees of freedom of motion.
6. The method of Embodiment 1, wherein when the metal is liquified, the alignment assembly has one or more degrees freedom of motion selected from the group consisting of X-axis translation, Y-axis translation, Z-axis translation, rotation about X-axis, rotation about Y-axis and rotation about Z-axis.
7. The method of Embodiment 1, wherein when the metal is solidified, the alignment assembly is restricted with respect to one or more degrees of freedom selected from the group consisting of X-axis translation, Y-axis translation, Z-axis translation, rotation about X-axis, rotation about Y-axis and rotation about Z-axis.
8. The method of Embodiment 1, wherein the alignment assembly is mechanically coupled to a plunger configured to contact the DUT at a first side of the DUT.
9. The method of Embodiment 9, wherein the device test equipment further comprises a contactor configured to contact the DUT at a second side of the DUT opposite the first side.
10. The method of Embodiment 10, wherein adjusting the alignment assembly into the position for electrical testing comprises aligning a surface of the plunger configured to contact the DUT to be substantially parallel to a surface of the contactor configured to contact the DUT.
11. The method of Embodiment 1, wherein the metal has a solidus temperature above a room temperature.
12. The method of Embodiment 1, wherein adjusting the alignment assembly into the position for electrical testing of the DUT comprises inserting an alignment DUT into the device test equipment with the metal in the liquid state.
13. The method of Embodiment 1, wherein the metal has a eutectic composition.
14. The method of Embodiment 14, wherein the eutectic composition has a eutectic melting temperature between room temperature and about 100° C.
15. The method of Embodiment 15, wherein the eutectic composition has a eutectic melting temperature between about 40° C. and about 80° C.
16. The method of Embodiment 16, wherein the eutectic composition has a eutectic melting temperature between about 55° C. and about 65° C.
17. The method of Embodiment 1, wherein the metal is essentially free of cadmium.
18. The method of Embodiment 1, wherein the metal is essentially free of lead.
19. The method of Embodiment 1, wherein the metal comprises bismuth (Bi), lead (Pb), indium (In), tin (Sn), and cadmium (Cd).
20. The method of Embodiment 20, wherein the metal comprises 40-50 weight % Bi, 18-28 weight % Pb, 14-24 weight % In, 3-13 weight % Sn, and 1-6 weight % Cd.
21. The method of Embodiment 20, wherein the metal comprises 45-55 weight % Bi, 22-32 weight % Pb, 8-18 weight % Sn, and 5-15 weight % Cd.
22. The method of Embodiment 1, wherein the metal comprises bismuth (Bi), indium (In), lead (Pb), and tin (Sn).
23. The method of Embodiment 23, wherein the metal comprises 44-54 weight % Bi, 16-26 weight % In, 13-23 weight % Pb, and 7-17 weight % Sn.
24. The method of Embodiment 1, wherein the metal comprises indium (In), bismuth (Bi), and tin (Sn).
25. The method of Embodiment 25, wherein the metal comprises 46-56 weight % In, 28-38 weight % Bi, and 11-21 weight % Sn.
26. An alignment system for positioning of an alignment assembly of a device test equipment, the alignment system comprising:
   the alignment assembly configured to align a device under test (DUT) for electrical testing; and
   a metal reservoir having disposed therein a metal configured to be controllably melted and solidified by the alignment system, the alignment assembly mechanically coupled to the metal in the metal reservoir,
   wherein the alignment assembly is configured to be adjusted into a position for electrical testing of the DUT with the metal in a liquid state, and
   wherein the alignment assembly is configured to be locked-in the position with the metal in a solid state.
27. The alignment system of Embodiment 27, wherein the alignment assembly is configured to be restricted with respect to one or more degrees of freedom of motion when the metal is in the solid state, and wherein the alignment assembly is further configured such that the restriction to the one or more degrees of freedom is removed when the metal is in the liquid state.
28. The alignment system of Embodiment 27, wherein the alignment system further comprises a heating assembly adjacent to the liquid metal reservoir for applying heat to the metal reservoir.
29. The alignment system of Embodiment 27, wherein the alignment system further comprises a cooling assembly adjacent to the liquid metal reservoir for actively cooling the metal reservoir.
30. The alignment system of Embodiment 27, wherein when the metal is liquified, the alignment assembly has one or more degrees freedom selected from the group consisting of X-axis translation, Y-axis translation, Z-axis translation, rotation about X-axis, rotation about Y-axis and rotation about Z-axis.

31. The alignment system of Embodiment 27, wherein when the metal is solidified, the alignment assembly is restricted with respect to one or more degrees of freedom selected from the group consisting of X-axis translation, Y-axis translation, Z-axis translation, rotation about X-axis, rotation about Y-axis and rotation about Z-axis.
32. The alignment system of Embodiment 27, wherein the alignment assembly is mechanically coupled to a plunger configured to contact the DUT at a first side of the DUT.
33. The alignment system of Embodiment 33, wherein the device test equipment further comprises a contactor configured to contact the DUT at a second side of the DUT opposite the first side.
34. The alignment system of Embodiment 34, wherein device test equipment is configured such that when the alignment assembly is in the position for electrical testing, a surface of the plunger configured to contact the DUT is aligned to be parallel to a surface of the contactor configured to contact the DUT.
35. The alignment system of Embodiment 27, wherein the metal has a solidus temperature above a room temperature.
36. The alignment system of Embodiment 27, wherein the metal has a eutectic composition.
37. The alignment system of Embodiment 37, wherein the eutectic composition has a eutectic melting temperature between room temperature and about 100° C.
38. The alignment system of Embodiment 37, wherein the eutectic composition has a eutectic melting temperature between about 40° C. and about 50° C.
39. The alignment system of Embodiment 37, wherein the eutectic composition has a eutectic melting temperature between about 55° C. and about 65° C.
40. The alignment system of Embodiment 27, wherein the metal is essentially free of cadmium.
41. The alignment system of Embodiment 27, wherein the metal is essentially free of lead.
42. The alignment system of Embodiment 27, wherein the metal comprises bismuth (Bi), lead (Pb), indium (In), tin (Sn), and cadmium (Cd).
43. The alignment system of Embodiment 43, wherein the metal comprises 40-50 weight % Bi, 18-28 weight % Pb, 14-24 weight % In, 3-13 weight % Sn, and 1-6% Cd.
44. The alignment system of Embodiment 43, wherein the metal comprises 45-55 weight % Bi, 22-32 weight % Pb, 8-18 weight % Sn, and 5-15 weight % Cd.
45. The alignment system of Embodiment 27, wherein the metal comprises bismuth (Bi), indium (In), lead (Pb), and tin (Sn).
46. The alignment system of Embodiment 46, wherein the metal comprises 44-54 weight % Bi, 16-26 weight % In, 13-23 weight % Pb, and 7-17 weight % Sn.
47. The alignment system of Embodiment 27, wherein the metal comprises indium (In), bismuth (Bi), and tin (Sn).
48. The alignment system of Embodiment 48, wherein the metal comprises 46-56 weight % In, 28-38 weight % Bi, and 11-21 weight % Sn.
49. A device test equipment, comprising:
   the alignment system of any one of Embodiments 27 to 49.

Unless the context clearly requires otherwise, throughout the description and the embodiments, the words “comprise,” “comprising,” “include,” “including,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, shall refer to this application as a whole and not to any particular portions of this application. Where the context permits, words in the Detailed Description using the singular or plural number may also include the plural or singular number, respectively. The words “or” in reference to a list of two or more items, is intended to cover all of the following interpretations of the word: any of the items in the list, all of the items in the list, and any combination of the items in the list. All numerical values provided herein are intended to include similar values within a measurement error.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states.

The teachings provided herein can be applied to other systems, not necessarily the systems described above. The elements and acts of the various embodiments described above can be combined to provide further embodiments. The acts of the methods discussed herein can be performed in any order as appropriate. Moreover, the acts of the methods discussed herein can be performed serially or in parallel, as appropriate.

While certain embodiments have been described, these embodiments have been presented by way of example only, and are not intended to limit the scope of the disclosure. Indeed, the novel methods and systems described herein may be embodied in a variety of other forms. Furthermore, various omissions, substitutions and changes in the form of the methods and systems described herein may be made without departing from the spirit of the disclosure. For example, while the disclosed embodiments are presented in given arrangements, alternative embodiments may perform similar functionalities with different components and/or circuit topologies, and some elements may be deleted, moved, added, subdivided, combined, and/or modified. Each of these elements may be implemented in a variety of different ways as suitable. Any suitable combination of the elements and acts of the various embodiments described above can be combined to provide further embodiments. The accompanying claims and their equivalents are intended to cover such forms or modifications as would fall within the scope and spirit of the disclosure. Accordingly, the scope of the present inventions is defined by reference to the claims.

1. A method of aligning device test equipment for electrical testing of at least one device under test (DUT), the method comprising:
liquifying a metal in an alignment assembly, wherein the alignment assembly comprises:
an anchoring shank having attached at an end thereof an anchoring member and having a vertical translational degree of freedom when the metal is molten,
the anchoring member at least partly submerged in the metal, and
a housing mechanically coupled to at least one thermal head to contact the at least one DUT and having defined therein a metal reservoir encapsulating the metal, the housing configured to have at least rotational degrees of freedom when the metal is molten;
adjusting an alignment between the anchoring shank and the housing such that the at least one thermal head is aligned with the at least one DUT for the electrical testing; and
solidifying the metal such that a relative position of the anchoring shank to the housing is fixed.

2. (canceled)

3. The method of claim 1, wherein adjusting the alignment between the anchoring shank and the housing comprises one or both of:
moving the anchoring shank along the vertical translational degree of freedom; and
rotating the housing about at least one rotational degree of freedom.

4. (canceled)

5. The method of claim 1, wherein prior to liquifying the metal, the alignment between the anchoring shank and the housing is restricted such that one or more degrees of freedom of motion is fixed; and wherein solidifying comprises restricting the one or more degrees of freedom of motion.

6. The method of claim 1, wherein liquifying the metal comprises applying heat to the metal reservoir from outside the metal reservoir.

7. The method of Claim 6, wherein solidifying comprises stopping applying heat to the metal reservoir.

8. The method of claim 1, wherein solidifying comprises applying active cooling to the metal reservoir.

9. (canceled)

10. (canceled)

11. (canceled)

12. (canceled)

13. (canceled)

14. (canceled)

15. The method of claim 1, wherein adjusting the alignment between the anchoring shank and the housing comprises contacting the at least one thermal head with the DUT on a first side of the DUT.

16. The method of claim 15, wherein adjusting the alignment between the anchoring shank and the housing further comprises contacting a contactor of the device test equipment with the DUT at a second side of the DUT opposite the first side.

17. The method of claim 1, wherein adjusting the alignment between the anchoring shank and the housing comprises aligning a surface of the at least one thermal head with the DUT to be substantially parallel to a surface of the DUT.

18. An alignment system for positioning of an alignment assembly of a device test equipment, the alignment system comprising:
an alignment assembly comprising:
an anchoring shank having attached at an end thereof an anchoring member and having a vertical translational degree of freedom when a metal is molten,
the anchoring member at least partly submerged in the metal, and
a housing mechanically coupled to at least one thermal head to contact a device under test (DUT) and having defined therein a metal reservoir encapsulating the metal, the housing configured to have at least rotational degrees of freedom when the metal is molten;
wherein when the metal is in a liquid state, an alignment between the anchoring shank and the housing is free to be adjusted for aligning the at least one thermal head with the DUT for electrical testing; and
wherein when the metal is in a solid state, a relative position of the anchoring shank to the housing is fixed.

19. The alignment system of claim 18, wherein the DUT is housed in a coupon, the DUT having one or more degrees of freedom within the coupon.

20. (canceled)

21. (canceled)

22. The alignment system of claim 18, wherein the alignment assembly further comprises a fluidic channel disposed in the housing and configured to circulate a fluid.

23. The alignment system of claim 22, wherein the fluidic channel is configured to circulate a heating fluid such that the metal is liquified from the solid state.

24. The alignment system of claim 23, wherein the fluidic channel is configured to stop circulating the heating fluid such that the liquified metal is solidified.

25. The alignment system of claim 22, wherein the fluidic channel is configured to circulate a cooling fluid such that the metal is solidified from the liquid state.

26. The alignment system of claim 18, wherein when the metal is in the liquid state, the alignment assembly has one or more degrees of freedom of motion selected from the group consisting of X-axis translation, Y-axis translation, Z-axis translation, rotation about X-axis, rotation about Y-axis and rotation about Z-axis.

27. The alignment system of claim 18, wherein when the metal is in the solid state, the alignment assembly is restricted with respect to one or more degrees of freedom selected from the group consisting of X-axis translation, Y-axis translation, Z-axis translation, rotation about X-axis, rotation about Y-axis and rotation about Z-axis.

28. The alignment system of claim 18, wherein adjusting the alignment between the anchoring shank and the housing comprises contacting the at least one thermal head with the DUT on a first side of the DUT.

29. The alignment system of claim 28, wherein adjusting the alignment between the anchoring shank and the housing further comprises contacting a contactor of the device test equipment with the DUT at a second side of the DUT opposite the first side.

30-47. (canceled)
